(19) United States
(12) Patent Application Publication
(10) Pub. No.: US 2025/0385027 A1
(43) Pub. Date: Dec. 18, 2025

(54) DEVICE FOR USE WITH AN ELECTRICAL COMPONENT, SYSTEM COMPRISING DEVICE FOR USE WITH AN ELECTRICAL COMPONENT, METHOD OF OPERATING ELECTRICAL COMPONENT

(71) Applicant: FEI Company, Hillsboro, OR (US)

(72) Inventors: Reinout Hartong, Eindhoven (NL); Corné Van Rooij, Eindhoven (NL)

(73) Assignee: FEI Company, Hillsboro, OR (US)

(21) Appl. No.: 18/875,003

(22) PCT Filed: Jun. 12, 2023
(86) PCT No.: PCT/IB2023/056028

§ 371 Date: Dec. 13, 2024

(30) Foreign Application Priority Data
Jun. 14, 2022 (EP) 22179009.0

(51) Int. Cl. H01C 1/06

(52) U.S. Cl. CPC H01C 1/06

(57) ABSTRACT

The present invention relates to a device for use with an electrical component, wherein the device is configured to surround at least a component portion of the electrical component at least partially around the axis thereby defining a region therebetween. The device comprises two members, wherein at least one of the members comprises at least one varying property that varies along an axis.

### FIELD

The present invention generally relates to technologies for use with electrical components. In particular, the present invention relates to devices, systems and methods of alleviating the effects of unwanted capacitance between an electrical component and its operating environment.

### BACKGROUND

Parasitic or stray capacitance can cause unavoidable and usually unwanted capacitance that exists between the parts of an electronic component or circuit simply because of their proximity to each other. When two electrical conductors at different voltages are close together, the electric field between them causes electric charge to be stored on them; this effect constitutes capacitance.

At low frequencies parasitic capacitance can usually be ignored, but in high frequency circuits it can be a significant problem and is often the factor limiting the operating frequency and bandwidth of electronic components and circuits. In closely spaced cables, parasitic capacitive coupling can cause crosstalk, which means the signal from one circuit bleeds into another, causing interference and unreliable operation.

U.S. Pat. No. 8,373,998 B2 discloses a resistor shield to minimize crosstalk and power supply interference. The shield includes multiple printed circuit board shields that are arranged between each of the input resistors on a main printed circuit board in the power meter. Each PCB shield has a conductive layer that provides the shielding against unwanted energy. The inventors in U.S. Pat. No. 8,373,998 B2 have also realized that a resistor sandwiched between two grounded PCB shields can look and behave like a capacitor. However, to solve this issue they teach arranging the resistors in a diagonal or parallel manner between each pair of PCB shields to prevent the resistor from movement. Since the capacitance is dependent on the distance between two conductive materials, fixing the distance between the resistor and PCB pair will produce a non-varying parasitic capacitance which can then be compensated for.

U.S. Pat. No. 7,498,696 B2 discloses a method for grading voltage and shielding a high voltage component in a printed circuit board (PCB). In particular, U.S. Pat. No. 7,498,696 B2 teaches configuring a plurality of second tracks, each constructed of a metal or an alloy and is provided at different locations along the length of a high voltage component. Moreover, each of the second tracks is coupled to a respective voltage source. This configuration forces the electric potential at specific locations along the length of the high voltage component, to become substantially equal to the electric potentials of second tracks corresponding to that specific location, thereby producing a substantially linear voltage distribution (grading) along the length of the high voltage component.

Shielding resistors with two cylindrical shields, provided on opposite sides of the resistor, is also known. Such shields aim at removing the electric field in the radial direction. However, they are either too bulky, or they do not provide a good matching between the electric potential around the resistor and the electric potential on the resistor.

Grading rings encircling an insulator that covers a conductor are also known. These grading rings cause the electric field to follow the voltage potential along the conductor, to thereby avoid a breakdown of the insulator. The grading rings are typically connected to a capacitive divider. Overall, such a solution is bulky and introduce a high capacitive load to the system, which is disadvantageous for systems with high bandwidth.

While known solutions in the prior art on dealing with parasitic capacitance may be satisfactory in some instances, they may have certain drawbacks and limitations. They can be bulky, not provide a good matching between the electric potential around the resistor and the electric potential on the resistor and can introduce a high capacitive load to the system, which is disadvantageous for systems with high bandwidth.

### SUMMARY

It is an object of the present invention to overcome or at least alleviate the shortcomings and disadvantages of the prior art.

According to a first aspect, the present invention relates to a device for use with an electrical component.

The device is configured to surround at least a component portion of the electrical component at least partially around an axis thereby defining a region therebetween. This way, the electrical component (or parts thereof) can be provided in an enclosure created by the device and therefore at least partially separated from the environment outside the enclosure. This can be advantageous as it can allow the device to electromagnetically shield the electrical component. Hence, electromagnetic interference between the electrical component and an environment wherein the electrical component is located can be reduced and/or blocked. Put differently, the device can be an electromagnetic shield for the electrical component.

Moreover, the device can be abutted and surrounded by said region between the electrical component and the device. The electrical field in the region can be influenced (mainly) by the electrical component itself and by the device. On the other hand, without the presence of the device, the electrical field around and in the vicinity of the electrical component can be influenced by the electrical component and other electrical conductors that can be present in the environment wherein the electrical component is located. Therefore, the device of the present invention can be advantageous because the electrical field in the region and any effects that it can have on the electrical component can be more predictable and therefore easier to compensated for, compared to the scenario wherein the device is not used.

The device comprises two members. At least one of the members comprises at least one varying property that varies along the axis. The at least one varying property can vary along the axis such that an effect caused by a capacitance between the electrical component and an environment wherein the electrical component is positioned can be reduced. As will be discussed further below, the at least one varying property can be a quantity of the members or a distance of the members from the axis. Configuring the members such that at least one of them comprises at least one varying property can allow the device to influence the electric field in the region (i.e., the electric field around the electrical component) in such a way that an effect caused by a capacitance between the electrical component and an environment wherein the electrical component is positioned can be reduced.

Thus, the device can be advantageous because even though it can create a parasitic capacitor with the electrical component, charging and/or discharging of said capacitor can be alleviated and/or preferably eliminated. As such, time delays that may be caused by the presence of said parasitic capacitor, when attempting to change the electric potential of the electrical component, can be reduced and/or preferably eliminated. Again, this can be achieved by configuring the device such that at least one of its members can comprise at least one varying property (e.g., a quantity or distance parameter) that can vary along the axis.

Throughout the document, the terms electric potential and voltage can be used interchangeably.

It will be understood that said axis, which can also be referred to interchangeably as a varying axis and/or as a longitudinal axis, is merely used herein to refer to a direction along which the at least one varying property can vary.

The axis can be a straight line indicating a straight direction.

The axis can be a central axis of the device.

The axis can be a central axis of the electrical component.

The axis can be parallel with a direction of flow of an electrical current through the electrical component. That is, the axis can be parallel with a direction along which the electric potential in or on the electrical component can change. For example, the electrical component can be a circuit element such as a resistor. In this example, the current can generally flow from one end (or terminal) of the resistor to the other. The electric potential may also decrease from one end of the resistor to the other. Therefore, the axis along which the at least one varying property can vary can be directed from one end (or terminal) to the other end (or terminal) of the electrical component.

The axis can be parallel with a gradient of the electric potential along the electrical component. This way the at least one varying property can vary along the same direction that the voltage in or on the electrical component can vary. As such, the device can influence the electric field in the region between the electrical component and the device such that it can match with the gradient of the electric potential change along the electrical component.

The axis can be a longitudinal axis of the electrical component. That is, the electrical component can extend along the axis.

In some embodiments, the electrical component can extend substantially longitudinally along the axis. That is the electrical component can be comprise a substantial longitudinal shape in the direction of the axis, i.e., it can comprise one dimension which can be larger than the other dimensions, said larger dimension measured along the axis.

The electrical component can comprise two component ends which can be opposite to each other and at different positions along the axis. The two component ends can refer to extremities of the electrical component in the direction of the axis. Alternatively or additionally, the two component ends can refer to electric terminals of the electrical components. Said electrical terminals can be configured to facilitate creating an electrical connection thereon. For example, one of the electrical terminals can be an input electrical port and the other one can be an output electrical port.

The device can comprise a first device end and a second device end opposite to each other and at different positions along the axis. The first device end and the second device end are jointly referred to as device ends. The first device end and the second device end can be extremities of the device in the direction of the axis.

A first one of the members can extend along the axis from the first device end, past a center of the device and towards the second device end. Similarly, a second one of the members can extend along the axis from the second device end, past a center of the device and towards the first device end. That is, the device can comprise two halves along the axis and each of said halves can comprise both of the members.

A minimum distance between the members can be at least 0.5 mm, preferably at least 1 mm. Put differently, the members can be spaced apart from each other by at least 0.5 mm, preferably by at least 1 mm. This can facilitate electrically insulating the members from each other. As such, the members can comprise different electrical potentials.

In some embodiments, the minimum distance between the members can be 1 mm.

The minimum distance between the members can be at least 0.5 mm and at most 1.5 mm, preferably at least 0.8 mm and at most 1.2 mm, more preferably at least 0.9 mm and at most 1.1 mm.

The members can be configured such that any radial line perpendicular with the axis can pass through at most one of the members.

Put differently, the members can be non-overlapping. This can be advantageous, as capacitance between the members can be reduced. That is, the members can be electrically conductive. As such, they can form a capacitor. By configuring the device such that the members do not overlap, can reduce the capacitance between the members. As a result, the capacitive load introduced by the device can be reduced.

The members can be coaxial. For example, both members can comprise the axis as a central axis.

The members can be electrically insulated from each-other. This can be advantageous as it can allow maintaining the members at different electrical potentials without causing a short circuit between the members.

Moreover, the members can be configured to be electrically conductive. This can be advantageous as it can allow connecting the members to an electrical energy source and therefore maintaining them at predetermined electric potential. This way, the members can create respective electric fields, thereby influencing the electric field in the region.

The members can be configured to be electrically connected to an electrical energy source. This way the electric potential of the members can be “forced” at predetermined or desired values. This can be particularly advantageous for reducing or eliminating charging and/or discharging of the capacitor created by the electrical component and the device.

The device can comprise a hollow cylindrical shape. This can be particularly easy to manufacture—as the device can be manufactured as a rectangular sheet and then wrapped to from a cylinder. Moreover, said shape can create an enclosure that can accommodate electrical components of different sizes.

The device can comprise a device through-hole. This way the electrical component and the device can be easily arranged such that the device can surround at least a component portion of the device at least partially.

The device through-hole can extend along the axis.

The device through-hole can be configured to accommodate the electrical component. In some embodiments, the device-through hole can be configured to accommodate electrical components of different sizes.

The device through-hole can comprise the region. Put differently, the device through-hole can refer to an enclosure created by the device that can accommodate the electrical component.

The members can be identical in shape. This way the members can have exactly opposite effects on the electric field in the region. Additionally or alternative, it can facilitate manufacturing the device.

The device can comprise a substrate layer configured to be electrically non-conductive. This can reduce the likelihood of the device creating a short circuit, for example, with the electrical component or with other electrical conductors that can be in the vicinity.

The substrate layer can be made of an electrically non-conductive material. The substrate layer can comprise a polyimide material. For example, The substrate layer can be a polyimide film.

The substrate layer can be continuous. Again, this can provide better electrical insulation and/or better support for other layers of the device.

The substrate layer can form at least a portion of an outer surface of the device.

The device can comprise a conductive layer configured to be electrically conductive. The conductive layer can be particularly advantageous to form the members of the device.

The conductive layer can comprise at least one conductive material.

At least one of the conductive materials can be a metal, such as, copper, gold, aluminium, iron or silver.

Preferably, the conductive layer can comprise copper.

The conductive layer can comprise two conductive layer portions that are electrically insulated from each other. Each member can comprise a respective one of the two conductive layer portions.

In some embodiments, the conductive layer can comprise two disjoint sets of conductive layer portions. Each of the two sets can comprise a plurality of conductive layer portions. All the conductive layer portions of the conductive layer can be spaced apart from each other. Layer portions within a set can be configured to be electrically connected to each other and layer portions of different sets can be electrically insulated from each other. Each member can comprise a respective one of the two conductive layer portions. Such an embodiment can be particularly advantageous as it can allow configuring or creating the members of the device by simply connecting conductive layer portions with each other thereby forming the two disjoint sets. This can for example allow reconfiguring the members multiple times depending on the application and/or the electrical component. One can for example configure a size of the members by simply connecting or disconnecting conductive layer portions from each other.

The conductive layer can be provided on the substrate layer. This way, the substrate layer can support and at least partially insulate electrically the conductive layer.

The conductive layer and the substrate layer can be glued together. However, this is merely exemplary and other attaching means can be also be possible.

The device can comprise a cover layer covering at least the conductive layer, such that the conductive layer can be between the substrate layer and the cover layer. The cover layer can support and/or electrically insulate the conductive layer.

The conductive layer and the cover layer can be glued together. However, this is merely exemplary and other attaching means can be also be possible.

The cover layer can be configured to be electrically non-conductive.

The cover layer can be made of an electrically non-conductive material.

The cover layer can comprise a polyimide material. For example, the cover layer can be a polyimide film.

The cover layer can form at least a portion of an outer surface of the device.

The outer surface of the device can be formed by the cover layer and the substrate layer.

In some embodiments, the conductive layer can be embedded on the substrate layer. For example, the substrate layer can be wrapped around the conductive layer.

Thus, the substrate layer can form the entire outer surface of the device.

In some embodiments, one of the members can comprises at least one tooth that can extend parallel to the axis. Alternatively or additionally, both of the members can comprise at least one respective tooth extending parallel to the axis. Alternatively or additionally, at least one of the members can comprise a plurality of teeth extending parallel to the axis. Alternatively or additionally, both of the members can respectively comprise a plurality of teeth extending parallel to the axis.

That is, the teeth protrude in a direction parallel with the axis. Put differently, the teeth can be perpendicular with a plane, wherein said plane is perpendicular with the axis. In other words, the teeth can protrude from a plane that is perpendicular with the axis.

The teeth can be advantageous as they can facilitate configuring at least one of the members to comprise a varying property. In particular, the teeth or tooth of at least one of the members can be shaped and/or distanced from said axis, thereby configuring the respective member with a varying property.

Each tooth can extend along the axis from a first half of the device to a second half of the device, wherein the first and the second halves of the device are separated by a plane perpendicular to the axis. This can allow each tooth and therefore the respective member to be present in each half of the device.

In some embodiments, each tooth can extend from the first device end, past the center of the device and towards the second device end. However, it will be understood that it may not be a necessity to have each tooth “start” exactly at one of the device ends.

For example, each tooth can comprise a maximum length along the axis, which can be at least 25% of a maximum length along the axis of the device. For example, if a dimension of the device measured parallel with the axis is one unit, then a dimension measured parallel with the axis of each tooth can be at least a quarter unit.

Each tooth can comprise a maximum length along the axis which can be at most 90% of a maximum length along the axis of the device.

Each tooth can comprise a maximum length along the axis which can be at least 25% and at most 90% of a maximum length along the axis of the device.

Each tooth can comprise a maximum length along the axis which can be at least 35% and at most 85% of a maximum length along the axis of the device.

Each tooth can comprise a maximum length along the axis which can be at least 50% of the maximum length along the axial direction of the device.

Generally, it can be advantageous to have each tooth start from a position along the axis which is near one of the device ends and end in a position along the axis whish is near the other one of the device end.

In some embodiments, at least one of the members can comprise at least 3 teeth.

In some embodiments, at least one of the members can comprise at most 50 teeth.

In some embodiments, at least one of the members can comprise at most 25 teeth.

In some embodiments, at least one of the members can comprise at least 3 teeth and at most 15 teeth.

In some embodiments, at least one of the members can comprise at least 5 teeth and at most 10 teeth.

In some embodiments, at least one of the members can comprise 5 teeth.

In some embodiments, at least one of the members can comprise 10 teeth.

Generally, more teeth can be more effective in reducing the effect of the capacitance between the electrical component and the device. For example, a device wherein each member respectively comprises 10 teeth can be more effective than a device wherein each member respectively comprises 5 teeth, or only one tooth. However, devices with less teeth can be easier to manufacture.

The teeth comprised by different members can be electrically insulated from each other. This can allow teeth from different members (and the members themselves) to comprise different electric potentials from each-other. As such, the teeth of different members can be configured to comprise opposite effects on the electrical component, which on itself can facilitate matching the electric potential on the region (which can be referred to as a second electric potential) with the electric potential of the electrical component (which can be referred to as a first electric potential) along the axis.

The teeth comprised by the same member can be electrically connected to each other. Therefore, the teeth of the same member can be configured with the same electric potential.

In some embodiments, the teeth can be identical to each other.

In some embodiments, the members can be configured such that each tooth can fit in a respective space between two neighbouring teeth of the other member. In other words, every other tooth of the device can belong to the same member. Put differently, the members can comprise interlocking teeth. This can be advantageous as teeth from different members can be neighbouring teeth and can be closely positioned to each other, therefore reducing the effect of each other on the electrical component.

In some embodiments, each tooth can comprise a respective tooth width spanning azimuthally with respect to the axis. The tooth width can be a dimension of a tooth measured along an azimuthal or lateral direction defined by the axis. It will be understood that each tooth comprises a respective tooth width for any position along the axis that the tooth extends.

Each tooth can be configured such that its respective tooth width can tapers along the axis. In other words, the presence or quantity of each tooth may reduce along the axis. Therefore, also the effect that said tooth can have, e.g., on the electrical component, may reduce, as well, along the axis.

The tooth width of each tooth may taper along the axis to zero. For example, the tooth can comprise a tip.

In some embodiments, each tooth width of each tooth can taper linearly along the axis. That is, the tooth can comprise straight edges.

For example, the teeth can comprise a shape resembling a trapezoid or triangle.

The tooth widths of teeth comprised by the same member can taper according to the same direction along the axis. Alternatively or additionally, the tooth widths of teeth comprised by the different members can taper according to opposite directions along the axis.

In some embodiments, particularly in embodiment wherein the tooth width of each tooth tapers, each tooth can be configured such that any point thereof is equally distanced from the axis. In other words, each tooth can be parallel with the axis.

Each tooth can comprise a respective tooth distance from the axis measured radially with respect to the axis. The tooth distance can be measured in a direction which can be perpendicular to the axis. The tooth distance can be an Euclidean distance of each tooth from the axis, at a particular position along the axis.

Each tooth can be configured such that its respective tooth distance can vary along the axis.

That is, each tooth can comprise a varying distance from the axis. Therefore, each tooth can comprise a varying distance from the electrical component. Therefore, each tooth can comprise a varying effect on the electrical component along the axis.

Each tooth can be configured such that its respective tooth distance can vary monotonically along the axis. That is, for each tooth, its respective tooth distance never decreases or never increases along the varying axis.

In some embodiments, each tooth can be configured such that its respective tooth distance can vary strictly monotonically along the axis. That is, for each tooth, its respective tooth distance always decreases or always increases along the varying axis.

In some embodiments, each tooth can be configured such that its respective tooth distance can varies linearly along the axis. That is, each tooth can be inclined or declined with respect to the axis.

The tooth distances of teeth comprised by the same member can increase according to the same direction along the axis.

Alternatively or additionally, the tooth distances of teeth comprised by different members can increase according to opposite directions along the axis. Put differently, moving along the axis, the teeth of one of the members approach the axis and the teeth of the other member get more distant from the axis.

In some embodiments, particularly on embodiments wherein the tooth distance varies along the varying axis, each tooth can comprise a constant tooth width along the axis.

Each tooth can be inclined with respect to the axis according to an inclination angle. The inclination angle with respect to the axis of the teeth of the same member can be the same. Alternatively or additionally, the inclination angle with respect to the axis of teeth of different members can comprise a difference of 180°.

In some embodiments, each tooth can be bent outwards with respect to the axis. That is, the tooth distance can vary non-linearly along the axis.

In some embodiments, at least one of the members can comprises a plurality of rings. Alternatively or additionally, both of the members respectively comprise a plurality of rings (153, 173). That is, instead of comprising teeth, in some embodiments the members may comprise rings.

The rings can be parallel to each other. That is, the rings may comprise cross-section which lie on parallel planes.

The rings can be coaxial. That is, all the rings can be arranged such that they can surround a central axis, which can for example be the axis along which the at least one varying property can vary.

That is, in some embodiments, a central axis of each ring can lie on the axis.

The rings can comprise a hollow cylindrical shape.

The rings can be spaced apparat from each other along the axis. That is, in some embodiments, no two rings can comprise the same or overlapping position along the varying axis.

The members can be configured such that any two neighbouring rings can belong to different members. Two rings can be neighbouring if there is no other ring between them. In other words, neighbouring rings can refer to rings that are arranged one after the other along the varying axis.

In some embodiments, at least one of the members can comprise at least 3 rings.

In some embodiments, at least one of the members can comprise at most 50 rings.

In some embodiments, at least one of the members can comprise at most 25 rings.

In some embodiments, at least one of the members can comprise at least 3 rings and at most 10 rings.

In some embodiments, at least one of the members can comprise at least 4 rings and at most 8 rings.

In some embodiments, at least one of the members can comprise 6 rings.

Generally, more rings can be more effective in reducing the effect of the capacitance between the electrical component and the device. For example, a device wherein each member respectively comprises 6 rings can be more effective than a device wherein each member respectively comprises 2 rings, or only one tooth. However, devices with less rings can be easier to manufacture.

In some embodiments, the rings comprised by the same member can be are electrically connected to each other. Therefore, the ring of the same member can be configured with the same electric potential.

The rings comprised by different members can be electrically isolated from each other. This can allow rings from different members (and the members themselves) to comprise different electric potentials from each-other. As such, the ring of different members can be configured to comprise opposite effects on the electrical component, which on itself can facilitate matching the electric potential on the region (which can be referred to as a second electric potential) with the electric potential of the electrical component (which can be referred to as a first electric potential) along the axis.

For each ring of one of the members there can be a corresponding identical ring comprised by the other member. Typically, said rings (which can be referred to as corresponding identical rings) can be symmetrical with respect to or equally spaced from, a central plane of the device that is perpendicular with the axis.

That is corresponding identical rings can be symmetric with respect to a center of the device along the axis.

In some embodiments, for at least one of the members a distance along the axis between two of its rings being furthest from each other is at least 25% of a maximum length along the axis of the device. Said distance can be indicative or the same with the maximum extension of each member along the axis. Alternatively or additionally, for at least one of the members a distance along the axis between two of its rings being furthest from each other can be at most 90% of a maximum length along the axis of the device. In some embodiments, said distance can be at least 25% and at most 90% of a maximum length along the axis of the device. Preferably said distance can be at least 35% and at most 85% of a maximum length along the axis of the device. For example, said distance can be at least 50% of the maximum length along the axial direction of the device.

In some embodiments, at least one of the members can comprise at least one ring on a first half of the device and at least one other ring on a second half of the device, wherein the first and the second halves of the device are separated by a plane perpendicular to the axis. That is, each member can comprise at least one respective ring on each side of the device along the axis.

Each ring can comprise a respective ring height measured along the axis. The ring height of each ring can respectively refer to an Euclidean distance between two planes perpendicular to the axis that abut the respective ring such that said ring is entirely in the space between the planes.

Each ring can be configured such that the respective ring height can depend on the position of the respective ring along the axis.

The rings comprised by the same member can comprise different ring heights. In other words, in some embodiments, there can be no two rings that comprise the same ring height and belong to the same member.

The ring height of rings comprised by the same member can vary monotonically, preferably strictly monotonically, along the axis. That is, the ring height of rings comprised by the same member if ordered based on the position of the respective rings on the varying axis can form a monotonic, preferably strictly monotonic, sequence of numbers. Put differently, for each member, the ring height can be a monotonic, preferably strictly monotonic, function of the position along the axis.

The ring height of rings comprised by one of the members and the ring height of rings comprised by the other one of the members can increase according to opposite directions along the axis. In other words, in a direction along the axis and along which one of the members can comprise rings with increasing ring height, the other member can comprise rings with decreasing ring height

In the preceding paragraphs, specific embodiments of the device comprising members with teeth or rings are discussed. However, the skilled person will appreciate that other shapes and configurations of the members can be possible.

In general, the at least one varying property can vary monotonically along the axis.

Preferably, the at least one varying property can vary strictly monotonically along the axis.

In some embodiments, the at least one varying property can vary linearly along the axis. This can be particularly advantageous, if the electrical component is a resistor, i.e., comprises a voltage which changes gradually along the axis.

In some embodiments, both members can respectively comprise at least one varying property that varies along the axis.

The members can be configured such that the at least one varying property of one of the members and the at least one varying property of the other one of the members can increase monotonically according to opposite directions along the axis. This can be particularly advantageous as it can allow a gradual change along the axis of an average electric potential in the region between the electrical component and the device.

Alternatively or additionally, the members can be configured such that the at least one varying property of one of the members and the at least one varying property of the other one of the members can increase strictly monotonically according to opposite directions along at least a portion the axis. Said portion can preferably be centrally aligned with the electrical component along the axis.

Alternatively or additionally, the members can be configured such that the at least one varying property of one of the members and the at least one varying property of the other one of the members can increase strictly monotonically according to opposite directions along the axis.

In some embodiments, the members can be configured such that the at least one varying property of one of the members and the at least one varying property of the other one of the members can increase linearly according to opposite directions along at least a portion the axis. Said portion can preferably be centrally aligned with the electrical component along the axis. A linear variation can be particularly advantageous if the electrical component is a resistor.

The members can be configured such that the at least one varying property of one of the members and the at least one varying property of the other one of the members increase linearly according to opposite directions along the axis. This can be particularly advantageous if the electrical component is a resistor.

In some embodiments, the members can be configured such that the at least one varying property of one of the members and the at least one varying property of the other one of the members can be equal at a center position along the axis of the device. This can be advantageous as typically, the electric potential of the electrical component (particularly, if the latter is a resistor) can be equal to the half the difference between the highest and lowest electrical potential of the electrical component.

One of the at least one varying property can depend on the tooth width of at least one tooth. That is, in embodiments wherein at least one member comprises at least one tooth, the tooth width can be the varying property or one of the varying properties. In other words, the members can be configured to reduce an effect caused by a capacitance between the electrical component and an environment wherein the electrical component is positioned by comprising at least one tooth with a varying tooth width.

In some embodiments, one of the at least one varying property can depend on the tooth distance of at least one tooth. That is, in embodiments wherein at least one member comprises at least one tooth, the tooth distance can be the varying property or one of the varying properties. In other words, the members can be configured to reduce an effect caused by a capacitance between the electrical component and an environment wherein the electrical component is positioned by comprising at least one tooth with a varying tooth distance.

In some embodiments, one of the at least one varying property can depend on the ring height of at least one ring. That is, in embodiments wherein at least one member comprises rings, the ring height can be the varying property or one of the varying properties. In other words, the members can be configured to reduce an effect caused by a capacitance between the electrical component and an environment wherein the electrical component is positioned by comprising rings with a varying ring height.

Generally, one of the at least one varying property can be a quantity parameter (which can interchangeably be referred to as a size parameter). The quantity parameter can be indicative of a quantity of the respective member comprised by the device at a plurality of positions along the axis. Therefore, the device can comprise different quantities of each member at different positions along the varying axis. The effect that each member can comprise on the electrical component can depend on the quantity (i.e., size) of each member. This is due to the rationale that the quantity of each member along the axis can correlate with the number of charges that each member can provide at particular positions along the varying axis.

In some embodiments, the quantity parameter can depend on the tooth width of at least one tooth. That is, in some embodiments providing at least one member with a varying quantity parameter can be realized by providing the at least one member with at least one tooth that comprises a varying tooth width along the axis.

In some embodiments, the quantity parameter can depend on the ring height of at least one ring. That is, in some embodiments providing at least one member with a varying quantity parameter can be realized by providing the at least one member rings that comprise different ring heights along the axis.

In some embodiments, one of the at least one varying property can be a distance parameter. The distance parameter can be indicative of a radial distance between the respective member and the axis measured radially with respect to the axis. It will be understood, that the further a member can be from the electrical component the lesser its effect on the electrical component can be. Therefore, the distance between the member and the electrical component can be varied such that an effect caused by a capacitance between the electrical component and an environment wherein the electrical component is positioned can be reduced.

The quantity parameter can depend on the tooth distance of at least one tooth. That is, in some embodiments providing at least one member with a varying distance parameter can be realized by providing the at least one member with at least one tooth that comprises a varying tooth distance along the axis.

In some embodiments, the device can be configured such that an effect caused by a capacitance between the electrical component and an environment wherein the electrical component can be positioned is reduced. The at least one varying property can therefore vary along the axis such that an effect caused by a capacitance between the electrical component and an environment wherein the electrical component is positioned can be reduced.

The environment wherein the electrical component is positioned can comprise at least one electrical conductor. The latter can couple with the electrical component, thereby forming parasitic capacitors between them. However, as knowledge of the number, size and/or electrical properties of said electrical conductors may not also be present, it can be hard to predict and/or account for the created parasitic capacitance between the electrical component and its environment. The device can act as an electromagnetic shield between the device and said at least electrical conductor. Put differently, the device can be advantageous as it can provide a controlled region around the electrical component. In this case the only or the dominant parasitic capacitance can be between the electrical component and the device; while parasitic couplings of the electrical component with other electrical conductor in the environment can be significantly reduced.

The environment wherein the electrical component can be positioned can comprise the device. That is, although the device can “block” parasitic couplings of the electrical component with other electrical conductors in the environment, the device can couple itself with the electrical component. Therefore, a parasitic capacitor can be created by the electrical component and the device. However, the device of the present invention can be advantageous as it can be configured (i.e., via the varying property) such that even the effects of said parasitic capacitor created by the electrical component and the device can be reduced.

Said capacitance between the electrical component and the environment can be an unwanted capacitance. For example, said capacitance between the electrical component and the environment can comprise a stray or parasitic capacitance.

As discussed, at least one of the members can comprise at least one varying property that varies along the axis such that an effect caused by a capacitance between the electrical component and an environment wherein the electrical component is positioned can be reduced

Said effect can comprises a charging time and/or a discharging time of a capacitor created by the electrical component and the environment wherein the electrical component. This can be achieved due to the fact that the device can act as an electromagnetic shield of the electric component.

Said effect can comprises a charging time and/or a discharging time of a capacitor created by the electrical component and the device. Put differently, the present device can be configured such that the parasitic capacitor created by the device and the electrical component may not charge or discharge—or at least the length of charging and discharging cycles is reduced.

Said effect can comprise a time delay in changing from a first set voltage to a second set voltage the electric potential of the electrical component. Parasitic capacitance can be particularly disadvantageous when trying to change the electric potential of the electrical component. This is due to the fact that the parasitic capacitance can add a delay due to the charging or discharging of parasitic capacitors. The at least one varying property can vary along the axis such that said time delay can be reduced.

Said effect can comprises a time delay in changing from a first set voltage to a second set voltage the electric potential of an external electrical device electrically connected with the electrical component. This can be the case, for example, when the electrical component can be a circuit element in a driving circuit for an external electrical device (e.g., an offset drift tube).

A first electric potential of the electrical component can vary along the axis.

In such embodiments, at least one of the properties can vary along the axis such that an axial electric field parallel to the axis in the region can match with a gradient of the first electric potential along the axis.

The axial electric field can match with the gradient of the first electric potential such that at any point within the region the axial electric field differs from the gradient of the first electric potential (V1) by no more than 10% of the gradient of the first electric potential (V1), preferably by no more than 5% of the gradient of the first electric potential (V1), even more preferably by no more than 1% of the gradient of the first electric potential (V1).

Preferably at least one of the properties can vary along the axis such that an axial electric field parallel to the axis in the region can be homogeneous within a tolerance of at most 10% deviation, preferably of at most 5% deviation, even more preferably of at 1% deviation. A homogenous axial electric field can be advantageous, particularly if the electrical component is a resistor, as the electric potential in the region can comprise a gradient which can be substantially constant throughout the region.

A first electric potential of the electrical component can vary along the axis and a second electric potential in the region can vary along the axis. In such embodiments, at least one of the properties can vary along the axis such that the second electric potential can match with the first electric potential along the axis.

The second electric potential can match with the first electric potential such that at any point within the region a measure of disparity between the second electric potential and the first electric potential is at most 10% of the first electric potential, preferably by at most 5% of the first electric potential, even more preferably at most 1% of the first electric potential.

The first electric potential can be indicative of an electric potential at a point in or on the electrical component.

The first electric potential can vary deterministically along the axis.

The first electric potential can vary monotonically along the axis.

The first electric potential can vary strictly monotonically along the axis.

The first electric potential can vary linearly along the axis.

The second electric potential can be an average of electric potentials on points within the region that comprise the same position along the axis.

The component portion can comprise a length along the axis of at least 45% of a length along the axis of the electrical component. That is, in some embodiments, the device can comprise a length along the varying axis which can be at least 45% of a length along the axis of the electrical component.

Alternatively, the component portion can be the entire electrical component. That is the device can be configured such that it comprises a maximum extension along the axis that is equal or larger than a maximum extension along the axis of the electrical component.

The device can be configured to completely surround the component portion laterally around the axis.

Alternatively, the device can be configured to surround the component portion laterally around the axis by at least 120°, preferably by at least 180°, even more preferably by at least 270°.

The device can be configured to be electrically connected to an electrical energy source. This can be advantageous as it can allow “forcing” the members at respective electric potentials such that charging and/or discharging of the parasitic capacitor created by the electrical component and the device can be alleviated and preferably eliminated.

The members can be configured to be electrically connected to a respective one of opposite terminals of the electrical energy source.

The device can be configured to be electrically connected with the same electrical energy source that the electrical component can be connected to.

Each member can be configured to be electrically connected to the electrical energy source such that each member can comprise the same electric potential as a respective one of the component ends. In other words, each member can be “forced” to be at the same electrical potential as a respective component end of the electrical component. This way, every time the electric potential of the electrical component is changed, a corresponding change can be made also to the electric potential of the members. As such, charging and/or discharging of the parasitic capacitor created by the electrical component and the device can be alleviated and preferably eliminated.

The electrical energy source can a direct current source. This can be advantageous in scenarios wherein the current provided to the electrical component is a direct current.

Alternatively, the electrical energy source can be an alternating current source. This can be advantageous in dynamic scenarios wherein the current provided to the electrical component is an alternating current, such as the case in high frequency circuits.

Each of the members can be configured to be electrically connected with a respective one of the component ends. In other words, each member can be “forced” to be at the same electrical potential as a respective component end of the electrical component. This way, every time the electric potential of the electrical component is changed, a corresponding change can be made also to the electric potential of the members. As such, charging and/or discharging of the parasitic capacitor created by the electrical component and the device can be alleviated and preferably eliminated.

That is, each member can be configured to be electrically connected with a respective one of the component ends such that each member and the respective component end can comprise the same electric potential.

For example, each member can be configured to be electrically connected with a respective one of the component ends with a wire. Wire herein can refer to any circuit element that can be configured to allow flow of electric current with no or very little impedance.

The electrical component can be configured as a resistor. In some embodiments, the electric component can be a resistor. In particular, the electric component can be a high-ohmic resistor.

For example, the electrical component can be a resistor with a resistance of at least 1 mega Ohm and at most 15 mega Ohm, preferably, at least 5 mega Ohm and at most 12 mega Ohm. In some embodiments, the electrical component can be a resistor with a resistance of (substantially) 7 mega Ohm (e.g., it can be between 6.5 to 7.5 mega Ohm). In some embodiments, the electric component can be a resistor with a resistance of (substantially) 10 mega Ohm (e.g., it can be between 9.5 to 10.5 mega Ohm). However, it will be understood that these values are merely exemplary. In particular, said values can be advantageous when the electrical component can be used in a voltage regulating circuit for an offset drift tube.

In some embodiments, the electrical component can comprise a resistor. For example, the electrical component can be a plurality of resistors.

In some embodiments, the electrical component can be a transistor.

In some embodiments, the electrical component can comprise a transistor. For example, the electrical component can be a plurality of transistor.

In some embodiments, the electrical component can comprise a plurality of circuit elements.

In some such embodiments, at least one circuit element can be a resistor. Alternatively or additionally, the circuit elements can be resistors. For example, the circuit elements can be a string of resistors electrically connected in series.

In some embodiments, the electrical component can be part of a voltage divider circuit.

The electrical component can be part of a control circuit for setting the voltage of a second device at at least one setpoint voltage.

The second device can be part of a charged particle microscopy system.

The second device can be part of an imaging system of a charged particle microscopy system.

The second device can be part of drift tube of a charged particle microscopy system. For example, the second device can be part of an offset drift tube. The use of the device of the present invention in such cases can be particularly advantageous, to be able to switch the voltage of the offset drift tube with as much of a high frequency as possible.

The device can be configured to reduce electromagnetic interference in an electrical circuit comprising the electrical component. As discussed, the device can be configured as an electromagnetic shield of the electrical component. That is, the device can be used as an electromagnetic shield of the electrical component.

The device can be configured to reduce a resistive-capacitive delay in an electrical circuit comprising the electrical component.

The device can be configured to be used in a charged particle microscopy system comprising the electrical component.

In some embodiments, the device can be configured to comprise an unwrapped state and a wrapped state. In the unwrapped state the device can be configured to be flat. Preferably, in the unwrapped state the device can be configured to comprise a rectangular shape.

The device can comprise the device through-hole in the wrapped state. That is, the device can be configured to be wrapped such that it can comprise a device through-hole. In other words, in the wrapped state the device can be configured to comprise a hollow cylindrical shape.

Generally, the device can be used in the wrapped state. That is, the device can surround at least a component portion of the electrical component at least partially around an axis in the wrapped state.

The device can be configured to be rendered from the unwrapped state to the wrapped state at least once. For example, the device can be provided in unwrapped state (which can facilitate transport of the device) and can be rendered to the wrapped state for use with an electrical component.

Preferably, the device can be configured to be rendered from the wrapped state to the unwrapped state and vice-versa a plurality of times. This can allow easily removing and installing the device for use with an electrical component.

For example, the device can be configured to be rendered from the unwrapped state to the wrapped state by attaching two opposite edges of the device to each other. The device can be configured such that said two opposite edges are securely and releasably attachable to each other.

In a further aspect a system comprising a device and an electrical component is disclosed. It will be understood that any of the features discussed above can apply mutatis mutandis to the system.

The device comprised by the system can be configured according to any of the preceding device embodiments.

Moreover, all the features discussed above with respect to the electrical component can apply mutatis mutandis to the electrical component comprised by the system.

The system can comprise an offset drift tube for use in a charged particle microscope and wherein the electrical component can be electrically connected with the offset drift tube. The offset drift tube can comprise a region traversable by a charged particle beam and can be configured to generate a magnetic field in said region.

The system can comprise a voltage regulating circuit for providing a bias voltage to the offset drift tube and wherein the voltage regulating circuit can comprise the electrical component.

The offset drift tube can be configured to generate the magnetic field based on the bias voltage.

The voltage regulating circuit can be configured to alternate the bias voltage between a plurality of setpoints. In some embodiments, the voltage regulating circuit can be configured to alternate the bias voltage between a plurality of setpoints with a frequency of at least 100 kHz, preferably at least 130 kHz. In particular, the voltage regulating circuit can be configured to alternate the bias voltage between a plurality of setpoints, such that, each bias voltage can be reached and maintained within 10 μs. Moreover, the voltage regulating circuit can be configured to set each bias voltage within 300 ppm (parts per million) of the set value. The device of the present invention can be facilitating the voltage regulating circuit in achieving these aims.

Moreover, the voltage regulating circuit can provide a step response of up to 5 kV, preferably up to 3 kV.

The system can comprise a charged particle microscope and wherein the charged particle microscope can comprise the electrical component. The charged particle microscope can be a transmission-type charged particle microscope, an electron microscope, a scanning electron microscope, a transmission electron microscope, a scanning transmission electron microscope and/or an electron energy loss spectrometer. Alternatively, the charged particle microscope can be an ion-based microscope.

The charged particle microscope can comprise a charged particle emitter configured to emit a beam of charged particles. The charged particle microscope can also comprise an imaging system configured to receive the beam of charged particles emitted by the charged particle emitter.

The charged particle microscope can comprise the offset drift tube. In particular, in some embodiments, the imaging system can comprise the offset drift tube.

In a further aspect the present invention relates to a method of operating an electrical component. It will be understood that any of the features discussed above can apply mutatis mutandis to said method. The method of operating an electrical component comprises providing a device surrounding at least a component portion of the electrical component at least partially around the axis thereby defining a region therebetween. The device comprises two members. At least one of the members comprises at least one varying property that varies along an axis.

In a further aspect the present invention relates to a method of operating a system. It will be understood that any of the features discussed above can apply mutatis mutandis to said method. The method of operating system comprises providing a device surrounding at least a component portion of the electrical component at least partially around the axis thereby defining a region therebetween. The device comprises two members. At least one of the members comprises at least one varying property that varies along an axis.

The provided device can be configured according to any of the preceding device embodiments.

Moreover, all the features discussed above with respect to the electrical component can apply mutatis mutandis to the electrical component of said methods.

Further still, the system can be configured according to any of the preceding system embodiments.

The method can comprise electrically connecting the device to an electrical energy source.

Electrically connecting the device to an electrical energy source can comprise electrically connecting each of the members to a respective one of opposite terminals of the electrical energy source.

Electrically connecting the device to an electrical energy source can comprise electrically connecting the device and the electrical component to the same electrical energy source.

The electrical energy source can be a direct current source. Alternatively, the electrical energy source can be an alternating current source.

The method can comprise maintaining each member and a respective one of the component ends at equal electric potentials.

The method can comprise electrically connecting each member with a respective one of the component ends.

The method can comprises alternating an electric potential of the members between a plurality of setpoints.

The method can comprise alternating an electric potential of the members between a plurality of setpoints with a frequency of at least 100 kHz, preferably at least 130 kHz.

The method can comprise alternating an electric potential of the electrical component.

The method can comprise alternating an electric potential of the members and an electric potential of the electrical component in synchronization.

The method can comprise alternating an electric potential of the members and an electric potential of the electrical component in synchronization such that a difference between an electric potential of each member and a respective one of the component ends can be minimized, preferably be zero.

The method can comprise using the device to surround at least the component portion of the electrical component at least partially around the axis.

In some embodiments, the method can comprise wrapping the device around at least the component portion of the electrical component.

The method can comprise aligning the device and the electrical component such that they are coaxial.

The method can comprise the device reducing an electromagnetic interference in an electrical circuit comprising the electrical component.

The method can comprise the device electromagnetically shielding the electrical component.

The method can comprise the device reducing a resistive-capacitive (RC) delay in an electrical circuit comprising the electrical component.

The method can comprise the device reducing an effect caused by a capacitance between the electrical component and an environment wherein the electrical component is positioned. Said capacitance between the electrical component and the environment can be an unwanted capacitance. For example, said capacitance between the electrical component and the environment can comprise a stray or parasitic capacitance.

The method can comprise using the device in a charged particle microscopy system comprising the electrical component.

In a further aspect, the present invention relates to a use of a device according to any of the preceding device embodiments to surround at least the component portion of the electrical component at least partially around the axis.

In a further aspect, the present invention relates to a use of a device according to any of the preceding device embodiments to reduce electromagnetic interference in an electrical circuit.

In a further aspect, the present invention relates to a use of a device according to any of the preceding device embodiments as an electromagnetic shield.

In a further aspect, the present invention relates to a use of a device according to any of the preceding device embodiments to reduce a resistive-capacitive (RC) delay in an electrical circuit.

In a further aspect, the present invention relates to a use of a device according to any of the preceding device embodiments in a charged particle microscopy system.

In a further aspect, the present invention relates to a use of a device according to any of the preceding device embodiments in a voltage regulating circuit for providing a bias voltage to an offset drift tube of a charged particle microscope.

In a further aspect, the present invention relates to a method comprising providing a device model of the device according to any of the preceding device embodiments, simulating a second electric potential in the region using a data processing system and revising the model of the device in dependence upon the second electric potential.

Said method can allow for an automatic determination of an optimized model of the device.

The method can comprise producing the device according to the revised device model of the device.

The method can comprise providing a component model of the electrical component comprising a first electric potential of the electrical component along an axis.

Revising the device model of the device can comprise determining for at least one of the members at least one varying property that can vary along the axis.

The method can comprise determining the at least one varying property such that a difference between the first electric potential and the second electric potential can be minimized.

The method can comprise providing a voltage difference threshold and determining the at least one varying property such that a difference between the first electric potential and the second electric potential is smaller than the voltage difference threshold.

The method can comprise determining the at least one varying property such that a difference between an axial electric field parallel to the axis in the region and a gradient of the first electric potential along the axis is minimized.

The method can comprise providing a gradient difference threshold and determining the at least one varying property such that a difference between an axial electric field parallel to the axis in the region and a gradient of the first electric potential along the axis is smaller than the field difference threshold.

The method can comprise determining the at least one varying property such that an effect caused by a capacitance between the electrical component and the device is minimized.

The method can comprise providing a capacitance threshold and determining the at least one varying property such that an effect caused by the capacitance between the electrical component and the device is smaller than the capacitance threshold.

The method can comprise determining the at least one varying property such that an axial electric field parallel to the axis in the region can be homogeneous.

The method can comprise providing a field variance threshold and determining the at least one varying property such that a measure of disparity of an axial electric field parallel to the axis in the region is smaller than the field variance threshold.

The method can comprise determining the at least one varying property such that a radial electric field radially directed with respect to the axis in the region is zero.

The method can comprise providing a radial field threshold and determining the at least one varying property such that a radial electric field radially directed with respect to the axis in the region is smaller than the radial field threshold.

In some embodiments, the method can comprise providing the device model such that the device can comprise teethed members, as discussed above.

Revising the device model of the device can comprise determining a shape of at least one tooth.

Revising the device model of the device can comprise determining a number of teeth comprised by each member.

Revising the device model of the device can comprise determining a length along the axis of each tooth.

Revising the device model of the device can comprise determining a position along the axis of each tooth.

Revising the device model of the device can comprise determining a position along the axis of each tooth with respect to the electrical component.

Revising the device model of the device can comprise determining an electric potential of each tooth as a function of the electric potential of the electrical component.

In some embodiments, the method can comprise providing the device model such that the device can comprises at least one tooth with a varying tooth width, as discussed above.

Revising the device model of the device can comprise determining for each tooth the respective tooth width along the axis.

In some embodiments, the method can comprise providing the device model such that the device can comprises at least one tooth with a varying tooth distance, as discussed above.

Revising the device model of the device can comprise determining for each tooth the respective tooth distance along the axis.

In some embodiments, the method can comprise providing the device model such that the device can comprises ring with a varying ring heigh, as discussed above.

Revising the device model of the device can comprise determining for each ring the respective ring height.

Revising the device model of the device can comprise determining a material of the device.

Simulating a second electric potential in the region using a data processing system can comprise the data processing system executing a finite element method.

Simulating a second electric potential in the region can comprise determining the second electric potential at a plurality of points within the region.

Simulating a second electric potential in the region can comprise determining the second electric potential on a cross-section of the region, said cross-section being parallel to the axis.

Simulating a second electric potential in the region can comprise determining the second electric potential on a portion of a cross-section of the region, said cross-section being parallel to the axis. Said portion of the cross-section can be a half cross-section section of the region.

The present technology is also defined by the following numbered embodiments.

Below, device embodiments will be discussed. Whenever reference is herein made to “device embodiments”, these embodiments are meant.

1. A device (1) for use with an electrical component (2),
wherein the device (1) is configured to surround at least a component portion (25) of the electrical component (2) at least partially around an axis (Z) thereby defining a region (3) therebetween and
wherein the device (1) comprises two members (15, 17),
wherein at least one of the members (15, 17) comprises at least one varying property (130, 150, 190) that varies along the axis (Z).

2. The device according to the preceding embodiment, wherein the electrical component (2) comprises two component ends (22, 24) opposite to each other and at different positions along the axis (Z).

3. The device according to any of the preceding embodiments, wherein the axis (Z) is a central axis (Z) of the device (1).

4. The device according to any of the preceding embodiments, wherein the axis (Z) is a central axis (Z) of the electrical component (2).

5. The device according to any of the preceding embodiments, wherein the axis (Z) is parallel with a direction of flow of an electrical current through the electrical component (2).

6. The device according to any of the preceding embodiments, wherein the axis (Z) is a longitudinal axis (Z) of the electrical component (2).

7. The device according to any of the preceding embodiments, wherein the electrical component (2) extends substantially longitudinally along the axis (Z).

8. The device according to any of the preceding embodiments, wherein the device (1) comprises a first device end (12) and a second device end (14) opposite to each other and at different positions along the axis (Z).

9. The device according to the preceding embodiment, wherein a first one of the members (15, 17) extends along the axis (Z) from the first device end (12), past a center of the device (1) and towards the second device end (14) and a second one of the members (15, 17) extends along the axis (Z) from the second device end (14), past a center of the device (1) and towards the first device end (12).

10. The device according to any of the preceding embodiments, wherein a minimum distance between the members (15, 17) is at least 0.5 mm, preferably at least 1 mm.

11 The device according to any of the preceding embodiments, wherein a minimum distance between the members (15, 17) is 1 mm.

12 The device according to any of the preceding embodiments, wherein a minimum distance between the members (15, 17) is at least 0.5 mm and at most 1.5 mm, preferably at least 0.8 mm and at most 1.2 mm, more preferably at least 0.9 mm and at most 1.1 mm.

13. The device according to any of the preceding embodiments, wherein the members (15, 17) are configured such that any radial line perpendicular with the axis (Z) passes through at most one of the members (15, 17).

14. The device according to any of the preceding embodiments, wherein the members (15, 17) are non-overlapping.

15. The device according to any of the preceding embodiments, wherein the members (15, 17) are coaxial.

16. The device according to any of the preceding embodiments, wherein the members (15, 17) are electrically insulated from each-other.

17. The device according to any of the preceding embodiments, wherein the members (15, 17) are configured to be electrically conductive.

18. The device according to any of the preceding embodiments, wherein the members (15, 17) are configured to be electrically connected to an electrical energy source.

19. The device according to any of the preceding embodiments, wherein the device (1) comprises a hollow cylindrical shape.

20. The device according to any of the preceding embodiments, wherein the device (1) comprises a device through-hole (19).

21. The device according to the preceding embodiment, wherein the device through-hole (19) extends along the axis (Z).

22. The device according to any of the 2 preceding embodiments, wherein the device through-hole (19) is configured to accommodate the electrical component (2).

23. The device according to any of the 3 preceding embodiments, wherein the device through-hole (19) comprises the region (3).

24. The device according to any of the preceding embodiments, wherein the members (15, 17) are identical in shape.

25. The device according to any of the preceding embodiments, wherein the device (1) comprises a substrate layer (102) configured to be electrically non-conductive.

26. The device according to the preceding embodiment, wherein the substrate layer (102) is made of an electrically non-conductive material.

27. The device according to any of the 2 preceding embodiments, wherein the substrate layer (102) comprises a polyimide material.

28. The device according to any of the 3 preceding embodiments, wherein the substrate layer (102) is a polyimide film.

29. The device according to any of the 4 preceding embodiments, wherein the substrate layer (102) is continuous.

30. The device according to any of the 5 preceding embodiments, wherein the substrate layer (102) forms at least a portion of an outer surface of the device (1).

31. The device according to any of the preceding embodiments, wherein the device (1) comprises a conductive layer (104) configured to be electrically conductive.

32. The device according to the preceding embodiment, wherein the conductive layer (104) comprises at least one conductive material.

33. The device according to the preceding embodiment, wherein at least one of the conductive materials is a metal, such as, copper, gold, aluminium, iron or silver.

34. The device according to any of the 3 preceding embodiments, wherein the conductive layer (104) comprises copper.

35. The device according to any of the 4 preceding embodiments, wherein the conductive layer (104) comprises two conductive layer portions (1045, 1047) that are electrically insulated from each other and each member (15, 17) comprises a respective one of the two conductive layer portions (1045, 1047).

36. The device according to any of the 5 preceding embodiments, wherein
the conductive layer (104) comprises two disjoint sets of conductive layer portions (1045, 1047),
each of the two sets comprises a plurality of conductive layer portions (1045, 1047),
all the conductive layer portions (1045, 1047) are spaced apart from each other,
layer portions (1045, 1047) within a set are configured to be electrically connected to each other,
layer portions (1045, 1047) of different sets are electrically insulated from each other,
each member (15, 17) comprises a respective one of the two conductive layer portions (1045, 1047).

37. The device according to any of the preceding embodiments and with the features of embodiments 25 and 31, wherein the conductive layer (104) is provided on the substrate layer (102).

38. The device according to the preceding embodiment, wherein the conductive layer (104) and the substrate layer (102) are glued together.

39. The device according to any of the 2 preceding embodiments, wherein the device (1) comprises a cover layer (106) covering at least the conductive layer (104), such that the conductive layer (104) is between the substrate layer (102) and the cover layer (106).

40. The device according to the preceding embodiment, wherein the conductive layer (104) and the cover layer (106) are glued together.

41. The device according to any of the 2 preceding embodiments, wherein the cover layer (106) is configured to be electrically non-conductive.

42. The device according to any of the 3 preceding embodiments, wherein the cover layer (106) is made of an electrically non-conductive material.

43. The device according to any of the 4 preceding embodiments, wherein the cover layer (106) comprises a polyimide material.

44. The device according to any of the 5 preceding embodiments, wherein the cover layer (106) is a polyimide film.

45. The device according to any of the 6 preceding embodiments, wherein the cover layer (106) forms at least a portion of an outer surface of the device (1).

46. The device according to the preceding embodiment, wherein the outer surface of the device (1) is formed by the cover layer (106) and the substrate layer (102).

47. The device according to any of the preceding embodiments and with the features of embodiments 25 and 31, wherein the conductive layer (104) is embedded on the substrate layer (102).

48. The device according to the preceding embodiment, wherein the substrate layer (102) forms the entire outer surface of the device (1).

49. The device according to any of the preceding embodiments, wherein at least one of the members (15, 17) comprises at least one tooth (155, 175) extending parallel to the axis (Z).

50. The device according to any of the preceding embodiments, wherein both of the members (15, 17) comprise at least one respective tooth (155, 175) extending parallel to the axis (Z).

51. The device according to any of the preceding embodiments, wherein at least one of the members (15, 17) comprise a plurality of teeth (155, 175) extending parallel to the axis (Z).

52. The device according to any of the preceding embodiments, wherein both of the members (15, 17) respectively comprise a plurality of teeth (155, 175) extending parallel to the axis (Z).

53. The device according to any of the 4 preceding embodiments, wherein each tooth (155, 175) extends along the axis from a first half of the device (1) to a second half of the device (1), wherein the first and the second halves of the device (1) are separated by a plane perpendicular to the axis (Z).

54. The device according to any of the 5 preceding embodiments and with the features of embodiment 8, wherein each tooth (155, 175) extends from the first device end (12), past the center of the device (1) and towards the second device end (14).

55. The device according to any of the 6 preceding embodiments, wherein each tooth (155, 175) comprises a maximum length along the axis (Z) which is at least 25% of a maximum length along the axis (Z) of the device (1).

56. The device according to any of the 7 preceding embodiments, wherein each tooth (155, 175) comprises a maximum length along the axis (Z) which is at most 90% of a maximum length along the axis (Z) of the device (1).

57. The device according to any of the 8 preceding embodiments, wherein each tooth (155, 175) comprises a maximum length along the axis (Z) which is at least 25% and at most 90% of a maximum length along the axis (Z) of the device (1).

58. The device according to any of the 9 preceding embodiments, wherein each tooth (155, 175) comprises a maximum length along the axis (Z) which is at least 35% and at most 85% of a maximum length along the axis (Z) of the device (1).

59. The device according to any of the 10 preceding embodiments, wherein each tooth (155, 175) comprises a maximum length along the axis (Z) which is at least 50% of the maximum length along the axial direction of the device (1).

60. The device according to any of the 11 preceding embodiments, wherein at least one of the members (15, 17) comprises at least 3 teeth (155, 175).

61. The device according to any of the 12 preceding embodiments, wherein at least one of the members (15, 17) comprises at most 50 teeth (155, 175).

62. The device according to any of the 13 preceding embodiments, wherein at least one of the members (15, 17) comprises at most 25 teeth (155, 175).

63. The device according to any of the 14 preceding embodiments, wherein at least one of the members (15, 17) comprises at least 3 teeth (155, 175) and at most 15 teeth.

64. The device according to any of the 15 preceding embodiments, wherein at least one of the members (15, 17) comprises at least 5 teeth (155, 175) and at most 10 teeth.

65. The device according to any of the 16 preceding embodiments, wherein at least one of the members (15, 17) comprises 5 teeth (155, 175).

66. The device according to any of the 17 preceding embodiments, wherein at least one of the members (15, 17) comprises 10 teeth (155, 175).

67. The device according to any of the 18 preceding embodiments, wherein the teeth (153, 173) comprised by different members (15, 17) are electrically insulated from each other.

68. The device according to any of the 19 preceding embodiments, wherein the teeth (155, 175) comprised by the same member (15, 17) are electrically connected to each other.

69. The device according to any of the 20 preceding embodiments, wherein the teeth (155, 175) are identical to each other.

70. The device according to any of the 21 preceding embodiments, wherein the members (15, 17) are configured such that each tooth (155, 175) fits in a respective space between two neighbouring teeth (175, 155) of the other member (15, 17).

71. The device according to any of the preceding embodiments 49 to 70, wherein each tooth (155, 175) comprises a respective tooth width (150) spanning azimuthally with respect to the axis (Z).

72. The device according to the preceding embodiment, wherein each tooth (155, 175) is configured such that its respective tooth width (150) tapers along the axis (Z).

73. The device according to any of the 2 preceding embodiments, wherein the tooth width (150) of each tooth (155, 175) tapers along the axis (Z) to zero.

74. The device according to any of the 3 preceding embodiments, wherein the tooth width (150) of each tooth (155, 175) tapers linearly along the axis (Z).

75. The device according to any of the 4 preceding embodiments, wherein each tooth (155, 175) comprises a triangular shape.

76. The device according to any of the 5 preceding embodiments, wherein the tooth widths (150) of teeth (155, 175) comprised by the same member (15, 17) taper according to the same direction along the axis (Z).

77. The device according to any of the 6 preceding embodiments, wherein the tooth widths (150) of teeth (155, 175) comprised by the different members (15, 17) taper according to opposite directions along the axis (Z).

78. The device according to any of the 7 preceding embodiments, wherein each tooth (155, 175) is configured such that any point thereof is equally distanced from the axis (Z).

79. The device according to any of the preceding embodiments and with the features of any of embodiments 49 to 52, wherein each tooth (155, 175) comprises a respective tooth distance (190) from the axis (Z) measured radially with respect to the axis (Z).

80. The device according to the preceding embodiment, wherein each tooth (155, 175) is configured such that its respective tooth distance (190) varies along the axis (Z).

81. The device according to any of the 2 preceding embodiments, wherein each tooth (155, 175) is configured such that its respective tooth distance (190) varies monotonically along the axis (Z).

82. The device according to any of the 3 preceding embodiments, wherein each tooth (155, 175) is configured such that its respective tooth distance (190) varies strictly monotonically along the axis (Z).

83. The device according to any of the 4 preceding embodiments, wherein each tooth (155, 175) is configured such that its respective tooth distance (190) varies linearly along the axis (Z).

84. The device according to any of the 5 preceding embodiments, wherein the tooth distances (190) of teeth (155, 175) comprised by the same member (15, 17) increase according to the same direction along the axis (Z).

85. The device according to any of the 6 preceding embodiments, wherein the tooth distances (190) of teeth (155, 175) comprised by different members (15, 17) increase according to opposite directions along the axis (Z).

86. The device according to any of the 7 preceding embodiments, wherein each tooth (155, 175) comprises a constant tooth width (150) along the axis (Z).

87. The device according to any of the 8 preceding embodiments, wherein each tooth (155, 175) is inclined with respect to the axis (Z) according to an inclination angle.

88. The device according to any of the 9 preceding embodiments, wherein each tooth (155, 175) is bent outwards with respect to the axis (Z).

89. The device according to any of the preceding embodiments 1 to 48, wherein at least one of the members (15, 17) comprises a plurality of rings (153, 173).

90. The device according to any of the preceding embodiments 1 to 48, wherein both of the members (15, 17) respectively comprise a plurality of rings (153, 173).

91. The device according to any of the 2 preceding embodiments, wherein the rings (153, 173) are parallel to each other.

92. The device according to any of the 3 preceding embodiments, wherein the rings (153, 173) are coaxial.

93. The device according to any of the 4 preceding embodiments, wherein a central axis of each ring (153, 173) lies on the axis (Z).

94. The device according to any of the 5 preceding embodiments, wherein the rings (153, 173) comprise hollow cylindrical shapes.

95. The device according to any of the 6 preceding embodiments, wherein the rings (153, 173) are spaced apparat from each other along the axis (Z).

96. The device according to any of the 7 preceding embodiments, wherein the members (15, 17) are configured such any two neighbouring rings (153, 173) belong to different members (15, 17).

97. The device according to any of the 8 preceding embodiments, wherein at least one of the members (15, 17) comprises at least 3 rings (153, 173).

98. The device according to any of the 9 preceding embodiments, wherein at least one of the members (15, 17) comprises at most 50 rings (153, 173).

99. The device according to any of the 10 preceding embodiments, wherein at least one of the members (15, 17) comprises at most 25 rings (153, 173).

100. The device according to any of the 11 preceding embodiments, wherein at least one of the members (15, 17) comprises at least 3 rings (153, 173) and at most 10 rings.

101. The device according to any of the 12 preceding embodiments, wherein at least one of the members (15, 17) comprises at least 4 rings (153, 173) and at most 8 rings.

102. The device according to any of the 13 preceding embodiments, wherein at least one of the members (15, 17) comprises 6 rings (153, 173).

103. The device according to any of the 14 preceding embodiments, wherein the rings (153, 173) comprised by the same member (15, 17) are electrically connected to each other.

104. The device according to any of the 15 preceding embodiments, wherein the rings (153, 173) comprised by different members (15, 17) are electrically isolated from each other.

105. The device according to any of the 16 preceding embodiments, wherein for each ring (153, 173) of one of the members (15, 17) there is a corresponding identical ring (173, 153) comprised by the other member (17, 15).

106. The device according to the preceding embodiment, wherein corresponding identical rings (153, 173) are symmetric with respect to a center of the device (1) along the axis (Z).

107. The device according to any of the 18 preceding embodiments, wherein for at least one of the members (15, 17) a distance along the axis (Z) between two of its rings (153, 173) being furthest from each other is at least 25% of a maximum length along the axis (Z) of the device (1).

108. The device according to any of the 19 preceding embodiments, wherein for at least one of the members (15, 17) a distance along the axis (Z) between two of its rings (153, 173) being furthest from each other is at most 90% of a maximum length along the axis (Z) of the device (1).

109. The device according to any of the 20 preceding embodiments, wherein for at least one of the members (15, 17) a distance along the axis (Z) between two of its rings (153, 173) being furthest from each other is at least 25% and at most 90% of a maximum length along the axis (Z) of the device (1).

110. The device according to any of the 21 preceding embodiments, wherein for at least one of the members (15, 17) a distance along the axis (Z) between two of its rings (153, 173) being furthest from each other is at least 35% and at most 85% of a maximum length along the axis (Z) of the device (1).

111. The device according to any of the 22 preceding embodiments, wherein for at least one of the members (15, 17) a distance along the axis (Z) between two of its rings (153, 173) being furthest from each other is at least 50% of the maximum length along the axial direction of the device (1).

112. The device according to any of the 23 preceding embodiments, wherein at least one of the members (15, 17) comprises at least one ring (153, 173) on a first half of the device (1) and at least one other ring (153, 173) on a second half of the device (1) wherein the first and the second halves of the device (1) are separated by a plane perpendicular to the axis (Z).

113. The device according to any of the 24 preceding embodiments, wherein each ring (153, 173) comprises a respective ring height (130) measured along the axis (Z).

114. The device according to the preceding embodiment, wherein each ring (153, 173) is configured such that the respective ring height (130) depends on the position of the respective ring (153, 173) along the axis (Z).

115. The device according to any of the 2 preceding embodiments, wherein rings (153, 173) comprised by the same member (15, 17) comprise different ring heights (130).

116. The device according to any of the 3 preceding embodiments, wherein the ring height (130) of rings (153, 173) comprised by the same member (15, 17) varies monotonically along the axis (Z).

117. The device according to any of the 4 preceding embodiments, wherein the ring height (130) of rings (153, 173) comprised by one of the members (15, 17) and the ring height (130) of rings (153, 173) comprised by the other one of the members (15, 17) increase according to opposite directions along the axis (Z).

118. The device according to any of the preceding embodiments, wherein the at least one varying property (130, 150, 190) varies monotonically along the axis (Z).

119. The device according to any of the preceding embodiments, wherein the at least one varying property (130, 150, 190) varies strictly monotonically along the axis (Z).

120. The device according to any of the preceding embodiments, wherein the at least one varying property (130, 150, 190) varies linearly along the axis (Z).

121. The device according to any of the preceding embodiments, wherein both members (15, 17) respectively comprise at least one varying property (130, 150, 190) that varies along the axis (Z).

122. The device according to the preceding embodiment, wherein the members (15, 17) are configured such that the at least one varying property (130, 150, 190) of one of the members (15, 17) and the at least one varying property (130, 150, 190) of the other one of the members (15, 17) increase monotonically according to opposite directions along the axis (Z).

123. The device according to any of the 2 preceding embodiments, wherein the members (15, 17) are configured such that the at least one varying property (130, 150, 190) of one of the members (15, 17) and the at least one varying property (130, 150, 190) of the other one of the members (15, 17) increase strictly monotonically according to opposite directions along at least a portion the axis (Z).

124. The device according to any of the 3 preceding embodiments, wherein the members (15, 17) are configured such that the at least one varying property (130, 150, 190) of one of the members (15, 17) and the at least one varying property (130, 150, 190) of the other one of the members (15, 17) increase strictly monotonically according to opposite directions along the axis (Z).

125. The device according to any of the 4 preceding embodiments, wherein the members (15, 17) are configured such that the at least one varying property (130, 150, 190) of one of the members (15, 17) and the at least one varying property (130, 150, 190) of the other one of the members (15, 17) increase linearly according to opposite directions along at least a portion the axis (Z).

126. The device according to any of the 5 preceding embodiments, wherein the members (15, 17) are configured such that the at least one varying property (130, 150, 190) of one of the members (15, 17) and the at least one varying property (130, 150, 190) of the other one of the members (15, 17) increase linearly according to opposite directions along the axis (Z).

127. The device according to any of the 6 preceding embodiments, wherein the members (15, 17) are configured such that the at least one varying property (130, 150, 190) of one of the members (15, 17) and the at least one varying property (130, 150, 190) of the other one of the members (15, 17) are equal at a center position along the axis (Z) of the device (1).

128. The device according to any of the preceding embodiments and with the features of embodiment 71, wherein one of the at least one varying property (150) depends on the tooth width (150) of at least one tooth (155, 175).

129. The device according to any of the preceding embodiments and with the features of embodiment 79, wherein one of the at least one varying property (190) depends on the tooth distance (190) of at least one tooth (155, 175).

130. The device according to any of the preceding embodiments and with the features of embodiment 113, wherein one of the at least one varying property (130) depends on the ring height (130) of at least one ring (153, 173).

131. The device according to any of the preceding embodiments, wherein one of the at least one varying property (130, 150) is a quantity parameter (130, 150).

132. The device according to the preceding embodiment, wherein the quantity parameter (130, 150) is indicative of a quantity of the respective member (15, 17) comprised by the device (1) at a plurality of positions along the axis (Z).

133. The device according to any of the 2 preceding embodiments and with the features of embodiment 71, wherein the quantity parameter (150) depends on the tooth width (150) of at least one tooth (155, 175).

134. The device according to any of the 3 preceding embodiments and with the features of embodiment 113, wherein the quantity parameter (150) depends on the ring height (130) of at least one ring (153, 173).

135. The device according to any of the preceding embodiments, wherein one of the at least one varying property (190) is a distance parameter (190).

136. The device according to the preceding embodiment, wherein the distance parameter (190) is indicative of a radial distance between the respective member (15, 17) and the axis (Z) measured radially with respect to the axis (Z).

137. The device according to any of the 2 preceding embodiments and with the features of embodiment 79, wherein the distance parameter (190) depends on the tooth distance (190) of at least one tooth (155, 175).

138. The device according to any of the preceding embodiments, wherein the device (1) is configured such that an effect caused by a capacitance between the electrical component (2) and an environment wherein the electrical component (2) is positioned is reduced.

139. The device according to any of preceding embodiments, wherein the at least one varying property (130, 150, 190) varies along the axis (Z) such that an effect caused by a capacitance between the electrical component (2) and an environment wherein the electrical component (2) is positioned is reduced.

140. The device according to the preceding embodiment, wherein the environment wherein the electrical component (2) is positioned comprises at least one electrical conductor.

141. The device according to any of the 2 preceding embodiments, wherein the environment wherein the electrical component (2) is positioned comprises the device (1).

142. The device according to any of the 3 preceding embodiments, wherein said capacitance between the electrical component (2) and the environment is an unwanted capacitance.

143. The device according to any of the 4 preceding embodiments, wherein said capacitance between the electrical component (2) and the environment comprises a stray or parasitic capacitance.

144. The device according to any of the 5 preceding embodiments, wherein the effect comprises a charging time and/or a discharging time of a capacitor created by the electrical component (2) and the environment wherein the electrical component (2).

145. The device according to any of the 6 preceding embodiments, wherein the effect comprises a charging time and/or a discharging time of a capacitor created by the electrical component (2) and the device (1).

146. The device according to any of the 7 preceding embodiments, wherein the effect comprises a time delay in changing from a first set voltage to a second set voltage the electric potential of the electrical component (2).

147. The device according to any of the 8 preceding embodiments, wherein the effect comprises a time delay in changing from a first set voltage to a second set voltage the electric potential of an external electrical device electrically connected with the electrical component (2).

148. The device according to any of the preceding embodiments, wherein a first electric potential (V1) of the electrical component (2) varies along the axis (Z) and
at least one of the properties (130, 150, 190) varies along the axis (Z) such that an axial electric field parallel to the axis (Z) in the region (3) matches with a gradient of the first electric potential (V1) along the axis (Z).

149. The device according to the preceding embodiment, wherein the axial electric field matches with the gradient of the first electric potential (V1) such that at any point within the region (3)
the axial electric field differs from the gradient of the first electric potential (V1) by no more than 10% of the gradient of the first electric potential (V1),
preferably by no more than 5% of the gradient of the first electric potential (V1),
even more preferably by no more than 1% of the gradient of the first electric potential (V1).

150. The device according to any of the preceding embodiments, wherein at least one of the properties (130, 150, 190) varies along the axis (Z) such that
an axial electric field parallel to the axis (Z) in the region (3) is homogeneous within a tolerance of at most 10% deviation, preferably of at most 5% deviation, even more preferably of at 1% deviation.

151. The device according to any of the preceding embodiments, wherein
a first electric potential (V1) of the electrical component (2) varies along the axis (Z) and
a second electric potential (V2) in the region (3) varies along the axis (Z) and
at least one of the properties (130, 150, 190) varies along the axis (Z) such that the second electric potential (V2) matches with the first electric potential (V1) along the axis (Z).

152. The device according to the preceding embodiment, wherein the second electric potential (V2) matches with the first electric potential (V1) such that at any point within the region (3) a measure of disparity between the second electric potential (V2) and the first electric potential (V1) is at most 10% of the first electric potential (V1), preferably by at most 5% of the first electric potential (V1), even more preferably at most 1% of the first electric potential (V1).

153. The device according to any of the 2 preceding embodiments and/or with the features of embodiment 148, wherein the first electric potential (V1) is indicative of an electric potential at a point in or on the electrical component (2).

154. The device according to any of the 3 preceding embodiments and/or with the features of embodiment 148, wherein the first electric potential (V1) varies deterministically along the axis (Z).

155. The device according to any of the 4 preceding embodiments and/or with the features of embodiment 148, wherein the first electric potential (V1) varies monotonically along the axis.

156. The device according to any of the 5 preceding embodiments and/or with the features of embodiment 148, wherein the first electric potential (V1) varies strictly monotonically along the axis.

157. The device according to any of the 6 preceding embodiments and/or with the features of embodiment 148, wherein the first electric potential (V1) varies linearly along the axis.

158. the device according to any of the 7 preceding embodiments, wherein the second electric potential (V2) is an average of electric potentials on points within the region (3) that comprise the same position along the axis (Z).

159. The device according to any of the preceding embodiments, wherein the component portion (25) comprises a length along the axis (Z) of at least 45% of a length along the axis (Z) of the electrical component (2).

160. The device according to any of the preceding embodiments and without the features of the preceding embodiment, wherein the component portion (25) is the entire electrical component (2).

161. The device according to the preceding embodiment, wherein the device (1) is configured such that it comprises a maximum extension along the axis (Z) that is equal or larger than a maximum extension along the axis (Z) of the electrical component (2).

162. The device according to any of the preceding embodiments, wherein the device (1) is configured to completely surround the component portion (25) laterally around the axis (Z).

163. The device according to any of the preceding embodiments, wherein the device (1) is configured to surround the component portion (25) laterally around the axis (Z) by at least 120°, preferably by at least 180°, even more preferably by at least 270°.

164. The device according to any of the preceding embodiments, wherein the device (1) is configured to be electrically connected to an electrical energy source.

165. The device according to the preceding embodiment, wherein the members (15, 17) are configured to be electrically connected to a respective one of opposite terminals of the electrical energy source.

166. The device according to any of the 2 preceding embodiments, wherein the device (1) is configured to be electrically connected with the same electrical energy source that the electrical component (2) is connected to.

167. The device according to any of the 3 preceding embodiments and with the features of embodiment 2, wherein each member (15, 17) is configured to be electrically connected to the electrical energy source such that
each member (15, 17) comprises the same electric potential as a respective one of the component ends (22, 24).

168. The device according to any of the 4 preceding embodiments, wherein the electrical energy source is a direct current source.

169. The device according to any of embodiments 164 to 167, wherein the electrical energy source is an alternating current source.

170. The device according to any of the preceding embodiments and with the features of embodiment 2, wherein each of the members (15, 17) is configured to be electrically connected with a respective one of the component ends (22, 24).

171. The device according to the preceding embodiment, wherein each member (15, 17) is configured to be electrically connected with a respective one of the component ends (22, 24) such that each member (15, 17) and the respective component end (22, 24) comprise the same electric potential.

172. The device according to any of the 2 preceding embodiments, wherein each member (15, 17) is configured to be electrically connected with a respective one of the component ends (22, 24) with a wire.

173. The device according to any of the preceding embodiments, wherein the electrical component (2) is a resistor (2).

174. The device according to any of the preceding embodiments, wherein the electrical component (2) comprises a resistor.

175. The device according to any of the preceding embodiments, wherein the electrical component (2) comprises a transistor.

176. The device according to any of the preceding embodiments, wherein the electrical component (2) comprises a plurality of circuit elements.

177. The device according to the preceding embodiment, wherein at least one circuit element is a resistor.

178. The device according to any of the 2 preceding embodiments, wherein the circuit elements are resistors.

179. The device according to any of the 3 preceding embodiments, wherein the circuit elements are a string of resistors electrically connected in series.

180. The device according to any of the preceding embodiments, wherein the electrical component (2) is part of a voltage divider circuit.

181. The device according to any of the preceding embodiments, wherein the electrical component (2) is part of a control circuit for setting the voltage of a second device at at least one setpoint voltage.

182. The device according to the preceding embodiment, wherein the second device is part of a charged particle microscopy system.

183. The device according to any of the 2 preceding embodiments, wherein the second device is part of an imaging system of a charged particle microscopy system.

184. The device according to any of the 3 preceding embodiments, wherein the second device is part of drift tube of a charged particle microscopy system.

185. The device according to any of the preceding embodiments, wherein the device (1) is configured to reduce electromagnetic interference in an electrical circuit comprising the electrical component (2).

186. The device according to any of the preceding embodiments, wherein the device (1) is configured as an electromagnetic shield of the electrical component (2).

187. The device according to any of the preceding embodiments, wherein the device (1) is configured to reduce a resistive-capacitive (RC) delay in an electrical circuit comprising the electrical component (2).

188. The device according to any of the preceding embodiments, wherein the device (1) is configured to be used in a charged particle microscopy system comprising the electrical component (2).

189. The device according to any of the preceding embodiments, wherein the device (1) is configured to comprise an unwrapped state and a wrapped state.

190. The device according to the preceding embodiment, wherein in the unwrapped state the device (1) is configured to be flat.

191. The device according to any of the 2 preceding embodiments, wherein in the unwrapped state the device (1) is configured to comprise a rectangular shape.

192. The device according to any of the 3 preceding embodiments and with the features of embodiment 20, wherein the device (1) comprises the device through-hole (19) in the wrapped state.

193. The device according to any of the 4 preceding embodiments, wherein in the wrapped state the device (1) is configured to comprise a hollow cylindrical shape.

194. The device according to any of the 5 preceding embodiments, wherein the device (1) is used in the wrapped state.

195. The device according to any of the 6 preceding embodiments, wherein the device (1) is configured to be rendered from the unwrapped state to the wrapped state at least once.

196. The device according to any of the 7 preceding embodiments, wherein the device (1) is configured to be rendered from the wrapped state to the unwrapped state and vice-versa a plurality of times.

197. The device according to any of the 8 preceding embodiments, wherein the device (1) is configured to be rendered from the unwrapped state to the wrapped state by attaching two opposite edges of the device (1) to each other.

198. The device according to the preceding embodiment, wherein the device (1) is configured such that said two opposite edges are securely and releasably attachable to each other.

Below, system embodiments will be discussed. These embodiments are abbreviated by the letter “S” followed by a number. Whenever reference is herein made to “system embodiments”, these embodiments are meant.

S1. A system comprising
a device (1) and an electrical component (2),
wherein the device (1) is configured to surround at least a component portion (25) of the electrical component (2) at least partially around the axis (Z) thereby defining a region (3) therebetween and
wherein the device (1) comprises two members (15, 17),
wherein at least one of the members (15, 17) comprises at least one varying property (130, 150, 190) that varies along an axis (Z).

S2. The system according to the preceding embodiment, where the device (1) is configured according to any of the preceding device embodiments.

S3. The system according to any of the preceding system embodiments, wherein the electrical component is configured according to any of the embodiments 173 to 184.

S4. The system according to any of the preceding system embodiments, wherein the system further comprises an offset drift tube for use in a charged particle microscope and wherein the electrical component (2) is electrically connected with the offset drift tube.

S5. The system according to the preceding embodiment, wherein the offset drift tube comprises a region traversable by a charged particle beam and wherein the offset drift tube is configured to generate a magnetic field in said region.

S6. The system according to any of the 2 preceding embodiments, wherein the system comprises a voltage regulating circuit for providing a bias voltage to the offset drift tube and wherein the voltage regulating circuit comprises the electrical component (2).

S7. The system according to the preceding 2 embodiments, wherein the offset drift tube is configured to generate the magnetic field based on the bias voltage.

S8. The system according to any of the 2 preceding embodiments, wherein the voltage regulating circuit is configured to alternate the bias voltage between a plurality of setpoints.

S9. The system according to any of the 3 preceding embodiments, wherein the voltage regulating circuit is configured to alternate the bias voltage between a plurality of setpoints with a frequency of at least 100 kHz, preferably at least 130 kHz.

S10. The system according to any of the 4 preceding embodiments, wherein the bias voltage changes by up to 5 kV, preferably by up to 3 kV.

S11. The system according to any of the preceding system embodiments, wherein the system further comprises a charged particle microscope and wherein the charged particle microscope comprises the electrical component (2).

S12. The system according to the preceding embodiment, wherein the charged particle microscope is a transmission-type charged particle microscope.

S13. The system according to any of the 2 preceding embodiments, wherein the charged particle microscope is an electron microscope.

S14. The system according to any of the 3 preceding embodiments, wherein the charged particle microscope is a scanning electron microscope.

S15. The system according to any of the 4 preceding embodiments, wherein the charged particle microscope is a transmission electron microscope.

S16. The system according to any of the 5 preceding embodiments, wherein the charged particle microscope is a scanning transmission electron microscope.

S17. The system according to any of the 6 preceding embodiments, wherein the charged particle microscope is an electron energy loss spectrometer.

S18. The system according to embodiment S11, wherein the charged particle microscope is an ion-based microscope.

S19. The system according to any of the 8 preceding embodiments, wherein the charged particle microscope comprises a charged particle emitter configured to emit a beam of charged particles.

S20. The system according to the preceding embodiment, wherein the charged particle microscope comprises an imaging system configured to receive the beam of charged particles emitted by the charged particle emitter.

S21. The system according to any of the 10 preceding embodiments and with the features of embodiment S4, wherein the charged particle microscope comprises the offset drift tube.

S22. The system according to the 2 preceding embodiments, wherein the imaging system comprises the offset drift tube.

Below, method embodiments will be discussed. These embodiments are abbreviated by the letter “M” followed by a number. Whenever reference is herein made to “method embodiments”, these embodiments are meant.

M1. A method of operating an electrical component (2) comprising
providing a device (1) surrounding at least a component portion (25) of the electrical component (2) at least partially around the axis (Z) thereby defining a region (3) therebetween,
wherein the device (1) comprises two members (15, 17) and
wherein at least one of the members (15, 17) comprises at least one varying property (130, 150, 190) that varies along an axis (Z).

M2. A method of operating a system comprising
providing a device (1) and an electrical component (2) such that the device (1) surrounds at least a component portion (25) of the electrical component (2) at least partially around the axis (Z) thereby defining a region (3) therebetween,
wherein the device (1) comprises two members (15, 17), and
wherein at least one of the members (15, 17) comprises at least one varying property (130, 150, 190) that varies along an axis (Z).

M3. The method according to any of the preceding method embodiments, where the device (1) is configured according to any of the preceding device embodiments.

M4. The method according to any of the 3 preceding embodiments, wherein the system is configured according to any of the preceding system embodiments.

M5. The method according to any of the preceding method embodiments, wherein the method comprises electrically connecting the device (1) to an electrical energy source.

M6. The method according to the preceding embodiment, wherein electrically connecting the device (1) to an electrical energy source comprises
electrically connecting each of the members (15, 17) to a respective one of opposite terminals of the electrical energy source.

M7. The method according to any of the 2 preceding embodiments, wherein electrically connecting the device (1) to an electrical energy source comprises
electrically connecting the device (1) and the electrical component (2) to the same electrical energy source.

M8. The method according to any of the 3 preceding embodiments, wherein the electrical energy source is a direct current source.

M9. The method according to any of embodiments M5 to M7, wherein the electrical energy source is an alternating current source.

M10. The method according to any of the preceding method embodiments wherein the device (1) comprises the features of embodiment 2 and wherein the method comprises maintaining each member (15, 17) and a respective one of the component ends (22, 24) at equal electric potentials.

M11. The method according to any of the preceding method embodiments wherein the device (1) comprises the features of embodiment 2 and wherein the method comprises electrically connecting each member (15, 17) with a respective one of the component ends (22, 24).

M12. The method according to any of the preceding method embodiments, wherein the method comprises alternating an electric potential of the members (15, 17) between a plurality of setpoints.

M13. The method according to any of the preceding method embodiments, wherein the method comprises alternating an electric potential of the members (15, 17) between a plurality of setpoints with a frequency of at least 100 kHz, preferably at least 130 KHz.

M14. The method according to any of the preceding method embodiments, wherein the method comprises alternating an electric potential of the electrical component (2).

M15. The method according to any of the preceding method embodiments, wherein the method comprises alternating an electric potential of the members (15, 17) and an electric potential of the electrical component (2) in synchronization.

M16. The method according to the preceding embodiment, wherein the device (1) comprises the features of embodiment 2 and wherein the method comprises alternating an electric potential of the members (15, 17) and an electric potential of the electrical component (2) in synchronization such that
a difference between an electric potential of each member (15, 17) and a respective one of the component ends (22, 24) is minimized.

M17. The method according to any of the 2 preceding embodiments, wherein the device (1) comprises the features of embodiment 2 and wherein the method comprises alternating an electric potential of the members (15, 17) and an electric potential of the electrical component (2) in synchronization such that
a difference between an electric potential of each member (15, 17) and a respective one of the component ends (22, 24) is 0.

M18. The method according to any of the preceding method embodiments, wherein the method comprises
using the device (1) to surround at least the component portion (25) of the electrical component (2) at least partially around the axis (Z).

M19. The method according to any of the preceding method embodiments, wherein the method comprises wrapping the device (1) around at least the component portion (25) of the electrical component (2).

M20. The method according to the preceding embodiment, wherein the method comprises aligning the device (1) and the electrical component (2) such that they are coaxial.

M21. The method according to any of the preceding method embodiments, wherein the method comprises the device (1) reducing an electromagnetic interference in an electrical circuit comprising the electrical component (2).

M22. The method according to any of the preceding method embodiments, wherein the method comprises the device (1) electromagnetically shielding the electrical component (2).

M23. The method according to any of the preceding method embodiments, wherein the method comprises the device (1) reducing a resistive-capacitive (RC) delay in an electrical circuit comprising the electrical component (2).

M24. The method according to any of the preceding method embodiments, wherein the method comprises the device (1) reducing an effect caused by a capacitance between the electrical component (2) and an environment wherein the electrical component (2) is positioned.

M25. The method according to the preceding embodiment, wherein said capacitance between the electrical component (2) and the environment is an unwanted capacitance.

M26. The method according to any of the 2 preceding embodiments, wherein said capacitance between the electrical component (2) and the environment comprises a stray or parasitic capacitance.

M27. The method according to any of the preceding method embodiments, wherein the method comprises using the device (1) in a charged particle microscopy system comprising the electrical component (2).

M28. The method according to any of the preceding method embodiments, wherein the electrical component is configured according to any of the embodiments 173 to 184.

Below, use embodiments will be discussed. These embodiments are abbreviated by the letter “U” followed by a number. Whenever reference is herein made to “use embodiments”, these embodiments are meant.

U1. Use of a device according to any of the preceding device embodiments to surround at least the component portion (25) of the electrical component (2) at least partially around the axis (Z).

U2. Use of a device according to any of the preceding device embodiments to reduce electromagnetic interference in an electrical circuit.

U3. Use of a device according to any of the preceding device embodiments as an electromagnetic shield.

U4. Use of a device according to any of the preceding device embodiments to reduce a resistive-capacitive (RC) delay in an electrical circuit.

U5. Use of a device according to any of the preceding device embodiments in a charged particle microscopy system.

U6. Use of a device according to any of the preceding device embodiments in a voltage regulating circuit for providing a bias voltage to an offset drift tube of a charged particle microscope.

Below, further method embodiments will be discussed. These embodiments are abbreviated by the letter “A” followed by a number. Whenever reference is herein made to “A” embodiments, these embodiments are meant.

A1. A method comprising:
providing a device model of the device (1) according to any of the preceding device embodiments;
simulating a second electric potential (V2) in the region (3) using a data processing system; and
revising the model of the device (1) in dependence upon the second electric potential (V2).

A2. The method according to the preceding embodiment wherein the method comprises producing the device (1) according to the revised device model of the device (1).

A3. The method according to any of the 2 preceding embodiments, wherein the method comprises providing a component model of the electrical component (2) comprising a first electric potential (V1) of the electrical component (2) along an axis (Z).

A4. The method according to any of the preceding “A” embodiments, wherein revising the device model of the device (1) comprises
determining for at least one of the members (15, 17) at least one varying property (130, 150, 190) that varies along the axis (Z).

A5. The method according to the preceding embodiment and with the features of embodiment A3, wherein the method comprises
determining the at least one varying property (130, 150, 190) such that a difference between the first electric potential (V1) and the second electric potential (V1) is minimized.

A6. The method according to any of the 2 preceding embodiments and with the features of embodiment A3, wherein the method comprises providing a voltage difference threshold and
determining the at least one varying property (130, 150, 190) such that a difference between the first electric potential (V1) and the second electric potential (V1) is smaller than the voltage difference threshold.

A7. The method according to any of the 3 preceding embodiments and with the features of embodiment A3, wherein the method comprises
determining the at least one varying property (130, 150, 190) such that a difference between an axial electric field parallel to the axis (Z) in the region (3) and a gradient of the first electric potential (V1) along the axis (Z) is minimized.

A8. The method according to any of the 4 preceding embodiments and with the features of embodiment A3, wherein the method comprises providing a gradient difference threshold and
determining the at least one varying property (130, 150, 190) such that a difference between an axial electric field parallel to the axis (Z) in the region (3) and a gradient of the first electric potential (V1) along the axis (Z) is smaller than the field difference threshold.

A9. The method according to any of the 5 preceding embodiments, wherein the method comprises determining the at least one varying property (130, 150, 190) such that an effect caused by a capacitance between the electrical component (2) and the device (1) is minimized.

A10. The method according to any of the 6 preceding embodiments, wherein the method comprises providing a threshold and determining the at least one varying property (130, 150, 190) such that an effect caused by the capacitance between the electrical component (2) and the device (1) is smaller than the threshold.

A11. The method according to any of the 7 preceding embodiments, wherein the method comprises determining the at least one varying property (130, 150, 190) such that an axial electric field parallel to the axis (Z) in the region (3) is homogeneous.

A12. The method according to any of the 8 preceding embodiments, wherein the method comprises providing a field variance threshold and determining the at least one varying property (130, 150, 190) such that a measure of disparity of an axial electric field parallel to the axis (Z) in the region (3) is smaller than the field variance threshold.

A13. The method according to any of the 9 preceding embodiments, wherein the method comprises determining the at least one varying property (130, 150, 190) such that a radial electric field radially directed with respect to the axis (Z) in the region (3) is zero.

A14. The method according to any of the 10 preceding embodiments, wherein the method comprises providing a radial field threshold and
determining the at least one varying property (130, 150, 190) such that a radial electric field radially directed with respect to the axis (Z) in the region (3) is smaller than the radial field threshold.

A15. The method according to any of the preceding “A” embodiments, wherein the method comprises providing the device model such that the device (1) comprises the features of any of embodiments 49 to 70.

A16. The method according to the preceding embodiment, wherein revising the device model of the device (1) comprises determining a shape of at least one tooth (155, 175).

A17. The method according to any of the 2 preceding embodiments, wherein revising the device model of the device (1) comprises determining a number of teeth (155, 175) comprised by each member (15, 17).

A18. The method according to any of the 3 preceding embodiments, wherein revising the device model of the device (1) comprises determining a length along the axis (Z) of each tooth (155, 175).

A19. The method according to any of the 4 preceding embodiments, wherein revising the device model of the device (1) comprises determining a position along the axis (Z) of each tooth (155, 175).

A20. The method according to any of the 5 preceding embodiments, wherein revising the device model of the device (1) comprises determining a position along the axis (Z) of each tooth (155, 175) with respect to the electrical component (2).

A21. The method according to any of the 6 preceding embodiments, wherein revising the device model of the device (1) comprises determining an electric potential of each tooth (155, 175) as a function of the electric potential of the electrical component (2).

A22. The method according to any of the preceding “A” embodiments, wherein the method comprises providing the device model such that the device (1) comprises the features of any of embodiment 71 and wherein revising the device model of the device (1) comprises determining for each tooth (155, 175) the respective tooth width (150) along the axis (Z).

A23. The method according to any of the preceding “A” embodiments, wherein the method comprises providing the device model such that the device (1) comprises the features of any of embodiment 79 and wherein revising the device model of the device (1) comprises determining for each tooth (155, 175) the respective tooth distance (190) along the axis (Z).

A24. The method according to any of the preceding “A” embodiments, wherein providing a device model of the device (1) comprises providing the device model such that the device (1) comprises the features of any of embodiments 113 and revising the device model of the device (1) in dependence upon the second electric potential (V2) comprises determining for each ring (153, 173) the respective ring height (130).

A25. The method according to any of the preceding “A” embodiments, wherein revising the device model of the device (1) comprises determining a material of the device (1).

A26. The method according to any of the preceding “A” embodiments, wherein simulating a second electric potential (V2) in the region (3) using a data processing system comprises the data processing system executing a finite element method.

A27. The method according to any of the preceding “A” embodiments, wherein simulating a second electric potential (V2) in the region (3) comprises determining the second electric potential (V2) at a plurality of points within the region (3).

A28. The method according to any of the preceding “A” embodiments, wherein simulating a second electric potential (V2) in the region (3) comprises determining the second electric potential (V2) on a cross-section of the region (3), said cross-section being parallel to the axis (Z).

A29. The method according to any of the preceding “A” embodiments, wherein simulating a second electric potential (V2) in the region (3) comprises determining the second electric potential (V2) on a portion of a cross-section of the region (3), said cross-section being parallel to the axis (Z).

A30. The method according to the preceding embodiment, wherein said portion of the cross-section is a half cross-section section of the region (3).

### BRIEF DESCRIPTION OF THE DRAWINGS

FIG. 1 illustrates a voltage around an electrical component when a shield known in the prior art is used;

FIG. 2 illustrates a voltage around an electrical component when a device according to embodiments the present invention is used;

FIGS. 3a-c depict a perspective, cutaway and unwrapped view of a device according to an embodiment of the present invention configured to completely surround an electrical component;

FIG. 4 is a perspective view of the device according to embodiments of the present invention configured to partly surround the electrical component;

FIG. 5 is a cutaway view of the device according to embodiments of the present invention configured to surround, at least in part, a component portion of the electrical component;

FIGS. 6a-9b illustrate different embodiments of the device comprising members with a varying quantity parameter;

FIG. 10 illustrates an embodiment of the device comprising members with a varying distance parameter;

FIG. 11 is a graph illustrating the electric potential at and near the electrical component and at the device;

FIGS. 12a-b illustrate layers that can be comprised by the device according to embodiments the present invention;

FIG. 13 depicts an embodiment of a microscopy system which can comprise the device of the present invention;

FIG. 14 illustrates respective step responses of an electrical circuit when its input voltage changes for different scenarios;

FIGS. 15a-b illustrate an electrical circuit wherein the device 1 is used.

### DETAILED DESCRIPTION OF THE DRAWINGS

In the following, exemplary embodiments of the invention will be described, referring to the figures. These examples are provided to facilitate further understanding of the invention, without limiting its scope. Moreover, in the following description, a series of features and/or steps are described. The skilled person will appreciate that unless required by the context, the order of features and steps is not critical for the resulting configuration and its effect. Further, it will be apparent to the skilled person that irrespective of the order of features and steps, the presence or absence of time delay between steps, can be present between some or all of the described steps.

The description of the figures first provides a brief description of known electromagnetic shields and problems thereof, before providing descriptions of exemplary embodiments of the present invention.

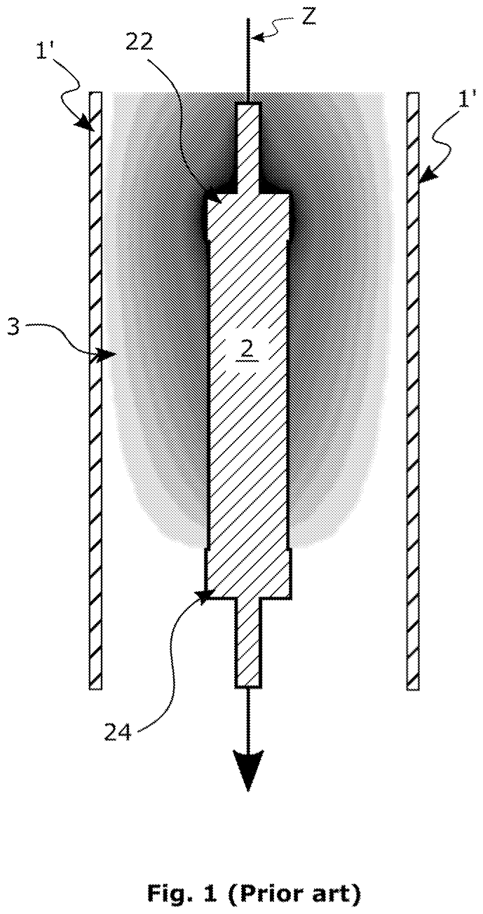

FIG. 1 shows a cross section of an electrical component 2 surrounded by a typical electromagnetic shield 1′, known in the art, which can interchangeably be referred to as a shield 1′ for the sake of brevity. The shield 1′ can surround the electrical component 2 such that a region 3 can be formed therebetween. FIG. 1 further illustrates an electric potential distribution within the region 3, wherein darker areas indicate a higher electric potential than brighter areas. Said electric potential can be obtained, for example, using a Finite Element Method (FEM) analysis. It can readily be noticed that around a first component end 22 (i.e., top component end 22) of the electrical component 2 the electric potential is higher, as indicated by the darker colors, than around a second component end 24 (i.e., bottom component end 24). Herein, the terms “top” and “bottom” refer to different positions along axis Z-which can also be referred to as the varying axis Z, for reasons that will become apparent further below.

During operation of the electrical component 2, an electric field can be created by the electrical component 2, which can extend in an operating environment wherein the electrical component 2 is located. Said operating environment may comprise environment elements such as electrical conductors, conducting surfaces and/or circuit elements. Therefore, the electric field generated by the electrical component 2 can encounter said environment elements that may be present in the operating environment. Similarly, the electric field created by environment elements in the operating environment can encounter the electrical component 2.

As a result, capacitance can be created between the electrical component and the environment elements in the operating environment. Generally, such a capacitance is unwanted and is generally referred to as a parasitic or stray capacitance. The parasitic capacitance can comprise negative effects on the operation of the electrical component 2 and/or of an electrical circuit comprising the electrical component 2. For example, the parasitic capacitance can cause crosstalk between the electrical component 2 and elements in the operating environment. In addition, it can cause resistive-capacitive delay, or RC delay, when changing a voltage applied to the electrical component 2 and/or when changing a voltage applied to elements in the operating environment. Thus, the parasitic capacitance can be a significant problem particularly in high-frequency circuits and can often be a limiting factor in increasing the operating frequency of high-frequency circuits.

As illustrated in FIG. 1, electromagnetic shielding is known to reduce crosstalk between an electrical component 2 and its operating environment. An electromagnetic shield 1′ may be formed by a continuous or mesh of a conductive material that creates an enclosure. The shield 1′ can generally be connected to ground (i.e., to the reference point of an electric circuit). This can block (or significantly reduce) electromagnetic fields from entering or leaving the said enclosure. By providing the electrical component 2 in the enclosure of the electromagnetic shield 1′—as shown in FIG. 1, capacitance and thus crosstalk between the electrical component 2 and environment elements in the operating environment can be alleviated and/or completely removed.

However, while capacitance between the electrical component 2 and environment elements outside the enclosure of the shield 1′ may be reduced or blocked by the use of the shield 1′, parasitic capacitance can still be present between the electrical component 2 and the shield 1′ itself. That is, on the one hand, the use of the shield 1′ can reduce parasitic capacitance between the electrical component 2 and the environment elements outside the enclosure of the shield 1′. However, on the other hand, the use of the shield 1′ introduces parasitic capacitance between the electrical component 2 and the shield 1′ itself. Moreover, the electrical component 2 or portions thereof can comprise a different electric potential than the shield 1′-which can typically be connected to ground. Said difference in electrical potential causes the parasitic capacitor created by the shield 1′ and electrical component 2 to charge and/or discharge, which as a result introduces delay in changing the voltage of the electrical component 2.

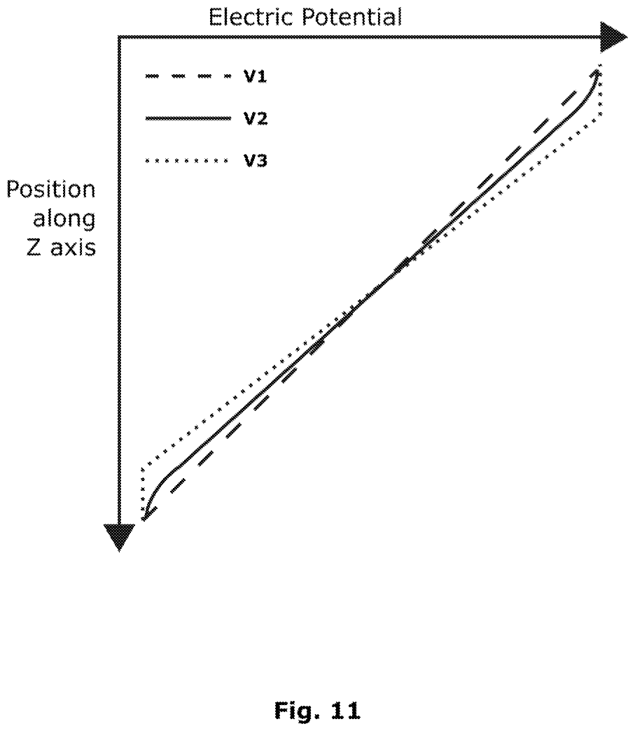

More particularly, the electrical component 2 can comprise an electric potential which varies along the axis Z. Said electric potential can also be referred to as a first electric potential V1 (see FIG. 11). For example, the electric potential at the top component end 22 can be higher than the electric potential at the bottom component end 24. Between the component ends 22, 24 the electric potential of the electrical component 2 can vary from the high voltage to the low voltage. For example, the electrical component 2 can be a resistor and the electric potential of the electrical component 2 may gradually decrease from one of the component ends 22, 24 to the other one. On the other hand, the shield 1′ formed by a continuous or mesh of a conductive material can comprise a constant voltage overall. Thus, portions of the electrical component 2 can face portions of the shield 1′ and the two can comprise different electric potentials.

This can be seen in FIG. 1, for example, by looking at the electric potential along a line perpendicular to the axis Z. At the bottom component end 24 the electric potential along said line is constant. This is due to the fact that the shield 1′ and the bottom component end 24 are connected to the ground, in this example. However, at the top component end 22 the voltage along said line decreases. The same is true at other positions along the axis Z, between the top component end 22 and the bottom component end 24.

As the voltage of the electrical component 2 and of the shield 1′ can be different, at least along a portion of the electrical component 2 along the axis Z, the parasitic capacitor created by them will charge and/or discharge. For example, when increasing the voltage applied at the top component end 22, because of the charging of the parasitic capacitance, there can be a delay between the time the applied voltage is increased and the time the voltage at the top component end 22 equals the applied voltage. The same can be true when decreasing the voltage applied at the top component end 22, because of the discharging of the parasitic capacitance.

Embodiments of the present invention provide a device 1 that can be configured to alleviate effects of parasitic capacitance from the electrical component towards its operating environment. This can reduce RC delay and allow for an increase of the operating frequency of the electrical circuit comprising the electrical component 2.

In general, the electrical component 2, with which the device 1 of the present invention can be used, can comprise an electrically conducting path, wherein the voltage along said path can vary when electric current flows through it. Put differently, an electric potential of the electrical component 1—referred to as a the first electric potential V1 (see FIG. 11)—can vary along an axis Z. The axis Z can be parallel with the direction of current flow through the electrical component 2. In other words, the axis Z can be parallel with said electrically conducting path. The electrical component can substantially extend longitudinally along the axis Z. That is, the axis Z can be a longitudinal axis of the electrical component 2.

Generally, and referring to all the Figures, the device 1 can comprise two members 15, 17. They can individually be referred to as a first member 15 and a second member 17 and jointly as members 15, 17. The members 15, 17 can be electrically insulated from each other. This can allow the members 15, 17 to be at different electric potentials from each other. In other words, different from known electromagnetic shields 1′, wherein the entire shield 1′ is at the same electric potential, the present device 1 comprises two members 15, 17 wherein each can comprise a respective electric potential. For example, one of the members 15, 17 can comprise a high voltage, while the other one of the members 15, 17 can comprise a low voltage. Preferably, each member 15, 17 can comprise the same electric potential as a respective one of the component ends 22, 24 of the electrical component 2.

The members 15, 17 can extend along the axis Z from opposite sides of the device 1 towards the center of the device 1 and preferably past the center of the device 1. Therefore, the members 15, 17 can extend from one side of the device 1 to the other side of the device 1 along the axis Z. The device 1 and the electrical component 2 can be arranged vis-à-vis each other such that the member 15, 17 with the higher electric potential can be aligned with the component end 22, 24 that comprises the higher electric potential and the member 15, 17 with the lower electric potential can be aligned with the component end 22, 24 that also comprises the lower first electric potential V1. This way, the difference between the voltage at the electrical component 2 and the voltage at the device 1, at the same position along the axis can be smaller—as compared to prior art shields 1′. Therefore, by merely comprising the two members 15, 17 the device 1 can already provide the advantage of reducing the effects caused by the capacitance between the electrical component 2 and the device 1—as compared to prior art electromagnetic shields 1′.

However, while the members 15, 17 can comprise different voltages from each other, they comprise a constant voltage within themselves. That is, the voltage along the axis Z of each member 15, 17 can be substantially constant. However, as discussed, the voltage of the electrical component 2 can vary along the axis Z. Thus, while the voltage at the component ends 22, 24 can be the same as the voltage of the respective member 15, 17, the voltage along the electrical component 2 can be different from the voltage of the members 15, 17.

For example, the voltage of the electrical component 2, which can be a resistor 2, can gradually decrease from the first component end 22 to the second component end 24. Thus, the voltage of the electrical component 2 can be highest at the first component end 22 and smallest at the second component end 24. The first member 15 can therefore comprise the high voltage of the first component end 22 and the second member 17 can comprise the low voltage of the second component end 24. Therefore, at the component ends 22, 24 the voltage between the electrical component 2 and the device 1 can match. However, at different positions between the component ends 22, 24 the voltage between the electrical component 2 and the device 1 can be different. In particular, at positions nearer to the first component end 22, the voltage of the electrical component 2 can be lower than the voltage of the device 1. Similarly, at positions nearer to the second component end 24, the voltage of the electrical component 2 can be higher than the voltage of the device 1.

To further reduce the effects of the capacitance between the device 1 and the electrical component 2, the device 1 can be configured such that at least one of the members 15, 17 can comprise at least one varying property 130, 150, 190 which can vary along the axis Z. The at least one varying property 130, 150, 190 can vary along the axis Z such that each member 15, 17 may cancel the effect of the other in a varying manner along the axis Z.

Continuing the above example, at positions nearer to the first component end 22, the voltage of the electrical component 2 can be lower than the voltage of the first member 15 and therefore a first electric field directed from the first member 15 to the electrical component 2 can be present. However, at such positions, the second member 17 can also be present which can comprise a lower voltage than the electrical component 2 at these positions. Therefore, a second electric field directed from the electrical component 2 to the second member 17 can be present. The first and the second electric field comprise opposite directions, i.e., oppose each other. These fields are also present at positions nearer to the second component end 24, but with opposite directions than described in the preceding sentences. An aim of the present invention can thus be to have the members 15, 17 and in particular the at least one varying property 130, 150, 190 configured such that the first and the second electric fields completely or at least significantly cancel each other at each position along the axis Z.

As it will be appreciated by the skilled person, for each position along the axis Z, each of the fields can depend on the quantity (i.e., amount) of the respective member 15, 17 at that position along the axis Z and on the distance between the electrical component 2 and the respective member 15, 17 at that position along the axis Z. More particularly, how much these fields can cancel each other out can depend on a ratio between a quantity of the first member 15 and a quantity of the second member 17 and/or on a ratio between a distance of the first member 15 from the electrical component 2 and a distance of the second member 17 from the electrical component 2.

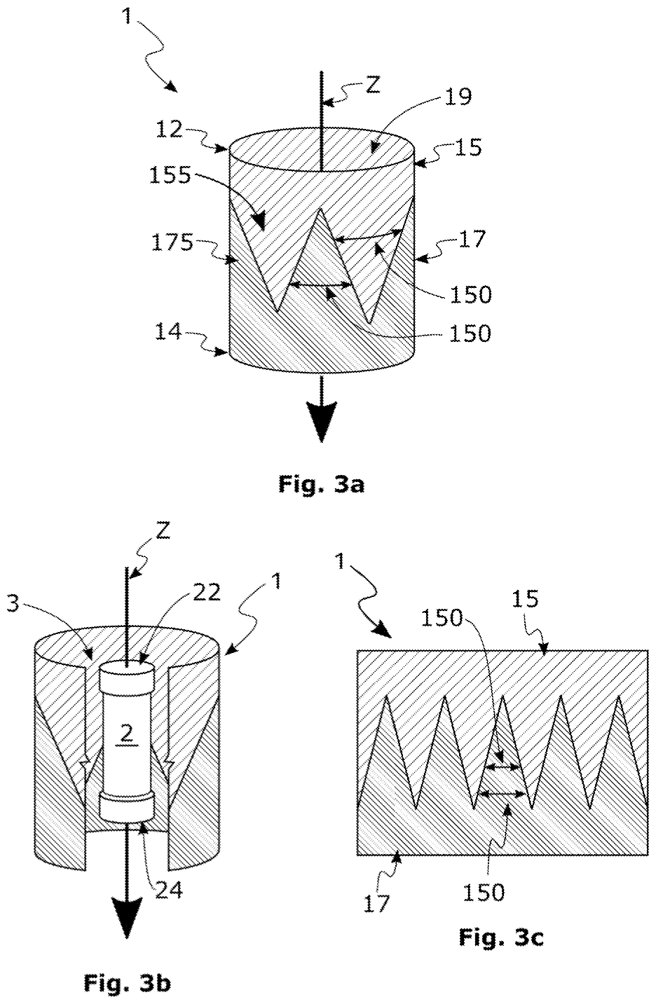

Thus, the varying property 130, 150, 190 can be a quantity parameter 130, 150 that can be indicative of a quantity of the respective member 15, 17 comprised by the device 1 at a plurality of positions along the axis Z. Continuing the above example, at a first component end 22 the device 1 can comprise only the first member 15. There can be no need for the second member 17 as the first member 15 and the first component end 22 can be at the same voltage. Moving along the axis Z and towards the second component end 22, the voltage of the device 1 can drop and therefore the first electric field can appear. It can become stronger the more the voltage of the device 1 drops along the axis Z. To cancel or reduce this field, the device 1 can comprise the second member 17 in an increasing quantity along the axis Z. Ideally, the second electric field can match the first electric field, such that they can cancel each other out. At the second component end 24, the device 1 can comprise only the second member 17. Again, there can be no need for the first member 15 as the second member 17 and the second component end 24 can be at the same voltage. This is illustrated in FIGS. 3a to 9b.

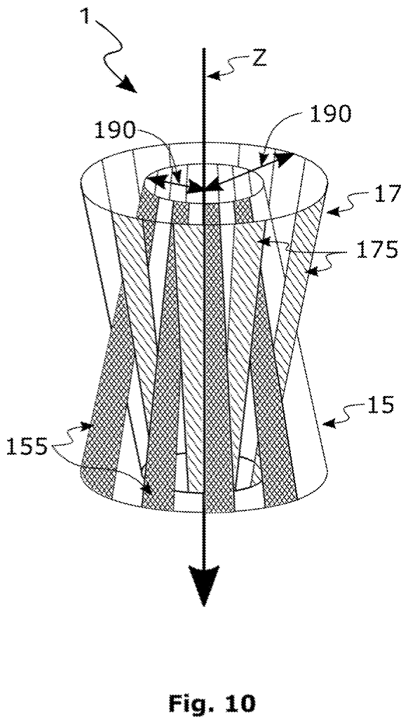

Additionally or alternatively, the varying property 130, 150, 190 can be a distance parameter 190 that can be indicative of a radial distance between the respective member 15, 17 and the axis Z measured radially with respect to the axis Z. Continuing the above example, at a first component end 22 the device 1 can comprise the first member 15 being closer to the electrical component 2 than the second member 17. The second member 17 may also not be present at the first component end 22 or it can be sufficiently distanced so that it comprises a negligible effect. Moving along the axis Z and towards the second component end 22, the voltage of the device 1 can drop and therefore the first electric field can appear. It can become stronger the more the voltage of the device 1 drops along the axis Z. To cancel or reduce this field, the device 1 can be configured such that the distance between the first member 15 and the electrical component 2 can increase. This can lower the first field. Alternatively or additionally, the device 1 can be configured such that the distance between the second member 17 and the electrical component 2 can decrease. This can increase the second field. Ideally, the second electric field can match the first electric field, such that they can cancel each other out. This is illustrated in FIG. 10.

The skilled person will understand that the above example is provided for illustrative purposes only to facilitate understanding of the invention. In general, by varying the quantity of at least one of the members 15, 17 along the axis Z and/or by varying the distance of at least one of the members 15, 17 along the axis Z an effect of the capacitance between the electrical component 2 and the device 1 can be reduced and preferably (or ideally) cancelled out.

Put differently, at least one of the members 15, 17 can be configured such that it can comprise at least one varying property 130, 150, 190 that varies along the axis Z such that an effect of a capacitance between the electrical component 2 and the device 1 can be reduced. Ideally, said effect can be cancelled out entirely. Via the at least one varying property 130, 150, 190 the device 1 can be configured such that there can be very little and ideally no charging or discharging of the parasitic capacitor formed by the electrical component 2 and the device 1. As such, the device 1 can have no impact on the speed of changing the electric potential of the electrical component 2. Thus, even though there can be capacitance between the electrical component 2 and the device 1, its effect can be reduced and ideally cancelled out.

An effect of the capacitance between the electrical component 2 and the device 1 can be a delay in changing an electrical potential of the electrical component. Said delay can be caused by the charging and/or discharging of said capacitor. Said delay can comprise a resistive-capacitive delay. Alternatively or additionally, an effect of the capacitance between the electrical component 2 and the device 1 can be a reduction of the maximum operating frequency of an electrical circuit comprising the electrical component 2. Alternatively or additionally, an effect of the capacitance between the electrical component 2 and the device 1, particularly when the electrical component is used in an amplifier circuit, can be the creation of a feedback current path between the input and output of the amplifier circuit. Said feedback current path can cause instability and/or parasitic oscillations in the amplifier.

Now the invention will be described with reference to the Figures.

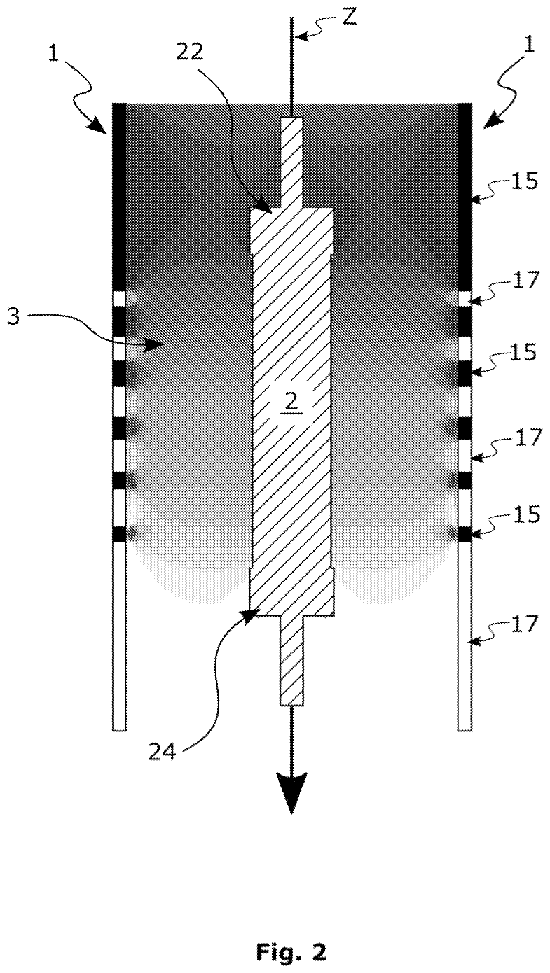

FIG. 2 depicts a cross section of the device 1 according to an embodiment of the present invention. The device 1 can surround the electrical component 2 such that a region 3 can be formed therebetween. FIG. 2 further illustrates an electric potential distribution within the region 3, wherein darker areas indicate a higher electric potential than brighter areas. Said electric potential can be obtained, for example, using a Finite Element Method (FEM) analysis. Moreover, said electric potential can also be referred to as a second electric potential V2-see FIG. 11. It can readily be noticed that around a first component end 22 (which can also be referred to as a top component end 22) of the electrical component 2, the electric potential is higher, as indicated by the darker colors, than around a second component end 24 (which can also be referred to as a bottom component end 24). Herein, the terms “top” and “bottom” refer to different positions along axis Z-which can also be referred to as a varying axis Z, for reasons that will become apparent further below.

In this particular embodiment, a quantity of each member 15, 17 varies along the axis Z. Moving from top to bottom along the axis Z, it can be seen that the device 1 initially consists only of the first member 15 and then its quantity reduces while the quantity of the second member 17 increases. As such, the electric potential in the region 3 gradually decreases along the axis Z—as indicated by the gradual increase of brightness in the region 3.

As shown by the FEM analysis, the device 1 can significantly cancel out radial electric fields in the region 3 between the device 1 and the electrical component 2. Radia electric field herein refers to an electric field directed perpendicularly to the axis Z, i.e., radially directed with respect to the axis Z. In addition, the device 1 can also homogenize axial electric fields in the region 3 between the device 1 and the electrical component 2. Axial electric field herein refers to electric fields directed parallel to the axis Z.

Referring now to FIGS. 3a to 3c, an embodiment of the device 1 comprising members 15, 17 which can be configured as toothed members 15, 17 is depicted. In particular, FIG. 3a depicts a perspective view of the device 1, FIG. 3b shows a cutaway view and FIG. 3c illustrates the device 1 in an unwrapped state.

Each of the members 15, 17 can comprise respective teeth 155, 175. In the depicted example, each member comprises 5 teeth; however, this is merely illustrative. Each of the teeth can comprise a respective tooth width 150. The tooth width 150 of each tooth 155, 175 can vary along the axis Z. In the depicted example, the tooth width 150 of each tooth 155, 175 varies along the axis Z linearly; however, this is merely illustrative. Therefore, the quantity of each member 15, 17 can vary along the axis. In other words, the tooth width 150 can be an example of the quantity parameter 130, 150 of the varying property 130, 150, 190. In particular, in the depicted example, the quantity of the first member 15 decreases in the direction from top to bottom along the axis Z and the quantity of the second member 17 increases in the direction from top to bottom along the axis Z.

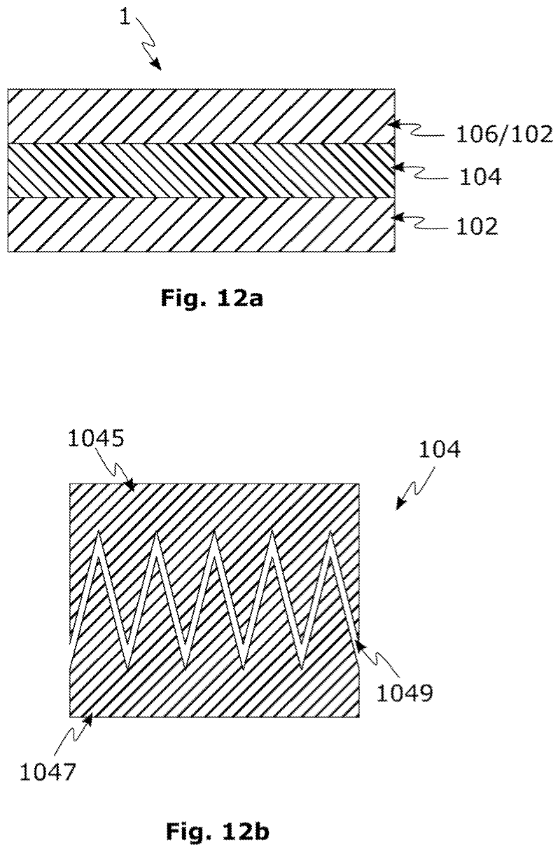

As depicted, the member 15, 17 can comprise interlocking teeth 155, 175. That is, each tooth 155, 175 can be positioned in the space between two neighboring teeth 155, 175 of the other member 15, 17. It will be understood that there can be some spacing (see FIG. 12b) in the boundary between the two members 15, 17 that can allow for electrical insulation between the two.

The device 1 can be rendered from the unwrapped state illustrated in FIG. 3c to the wrapped state illustrated in FIG. 3a. In the latter state, the device 1 can comprise a through-hole 19 and can be configured such that the through-hole 19 can accommodate the electrical component 2. This way, the device 1 can surround the electrical component 2. The region 3 can be created therebetween. It will be understood that the region 3 can also refer to the boundary between the device 1 and the electrical component 2—i.e., the device 1 can be wrapped around the electrical component 2 abutting the outer surface of the electrical component 2. In this case, electrical insulation may be needed between the electrical component 2 and the device 1.

The embodiment illustrated in FIG. 3 surrounds the entire electrical component 2 completely around the axis Z. However, this may not always be necessary.

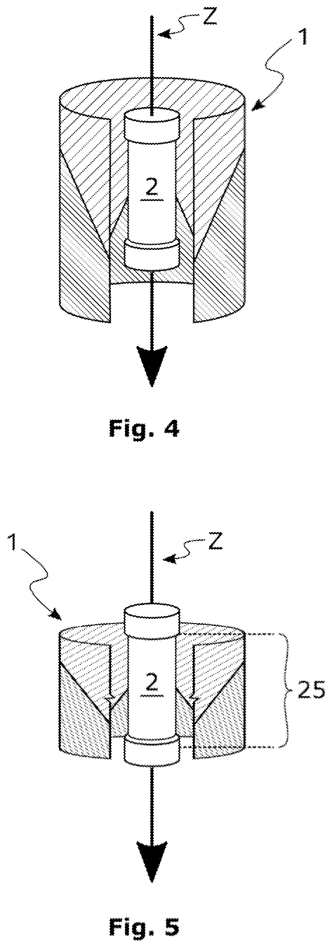

FIG. 4 depicts another embodiment of the device 1. As depicted, the device 1 can surround the entire electrical component 2 partially around the axis Z. Otherwise, the device 1 illustrated in FIG. 4 can comprise any of the features discussed above with respect to the device 1. Generally, such a solution can be inferior to the one illustrated in FIG. 3 with respect to the reduction of the effects caused by the capacitance between the electrical component 2 and the device 1.

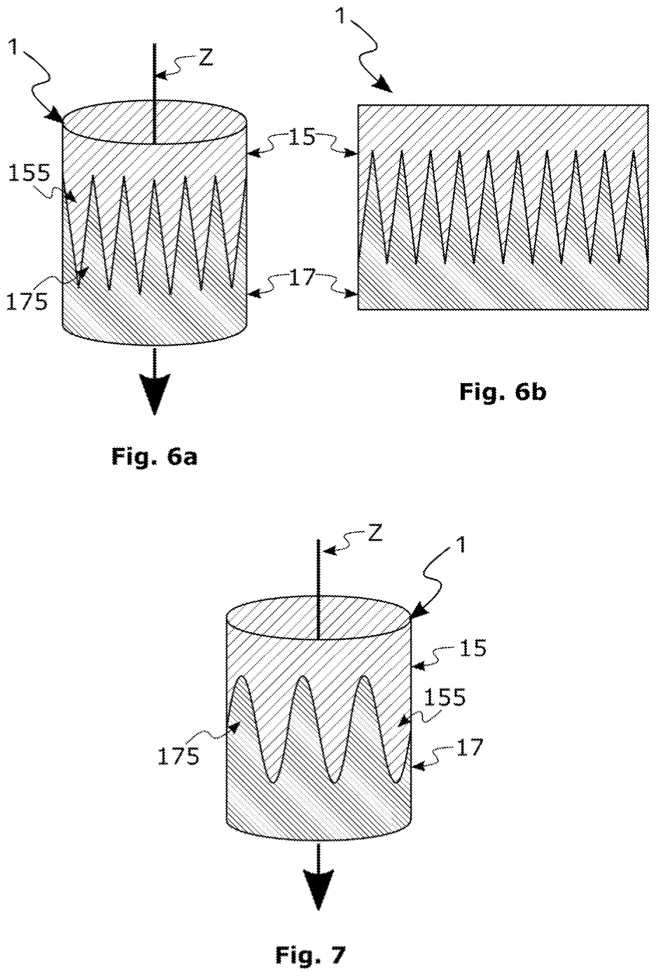

FIG. 5 depicts a cutaway view of another embodiment of the device 1. As depicted, the device 1 can surround a component portion 25 of the electrical component 2 partially or completely around the axis Z. Otherwise, the device 1 illustrated in FIG. 5 can comprise any of the features discussed above with respect to the device 1. Generally, such a solution can be inferior to the one illustrated in FIG. 3 with respect to the reduction of the effects caused by the capacitance between the electrical component 2 and the device 1.

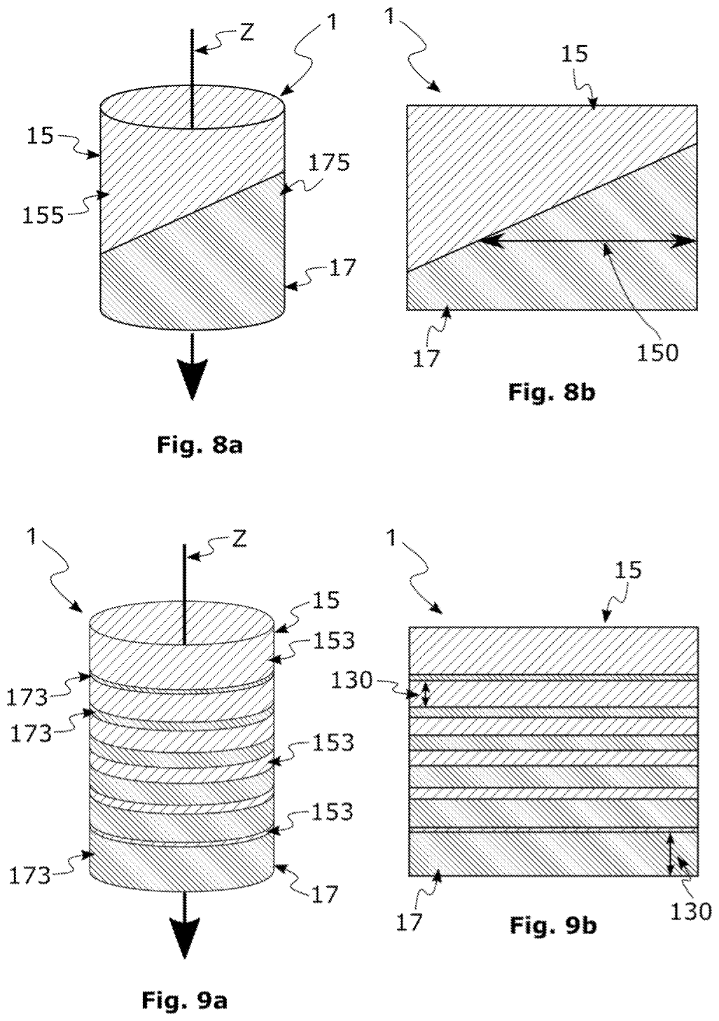

FIGS. 6a and 6b depict another embodiment of the device 1. As depicted, each of the members 15, 17 comprises 10 teeth 155, 17, respectively. Otherwise, the device 1 illustrated in FIGS. 6a and 6b can comprise any of the features discussed above with respect to the device 1. Generally, such a solution can be superior to the one illustrated in FIG. 3 with respect to the reduction of the effects caused by the capacitance between the electrical component 2 and the device 1. Generally, the more teeth 155, 175 a device can comprise the better it can reduce the effects caused by the capacitance between the electrical component 2 and the device 1.

The embodiments illustrated in FIGS. 3 to 6b comprise triangular teeth. However, this may not always be necessary. Typically, if the electrical component 2 comprises an electrical voltage which varies linearly along the axis Z (typically the case if the electrical component 2 is a resistor 2) triangular teeth may be advantageous.

FIG. 7 depict another embodiment of the device 1. As depicted, each of the members 15, 17 comprises teeth 155, 175 with curved edges. That is, the tooth with 150 of each tooth 155, 175 varies non-linearly along the axis Z. Otherwise, the device 1 illustrated in FIG. 7 can comprise any of the features discussed above with respect to the device 1. Generally, such a solution may be superior to the one illustrated in FIG. 3 with respect to the reduction of the effects caused by the capacitance between the electrical component 2 and the device 1 if the voltage of the electrical component 2 along the axis does not vary linearly.

FIGS. 8a and 8b depict another embodiment of the device 1. As depicted, each of the members 15, 17 comprises only one tooth 155, 175, respectively. Moreover, the teeth 155, 175 do not comprise a bilateral triangle shape, but rather a right triangle shape; however again this is only illustrative. Otherwise, the device 1 illustrated in FIGS. 8a and 8b can comprise any of the features discussed above with respect to the device 1. Generally, such a solution can be inferior to the one illustrated in FIG. 3 with respect to the reduction of the effects caused by the capacitance between the electrical component 2 and the device 1. However, it might be easier to manufacture.

Referring now to FIGS. 9a and 9b, another embodiment of the device 1 comprising members 15, 17 which can be configured as ringed members 15, 17 is depicted. In particular, FIG. 9a depicts a perspective view of the device 1 and FIG. 9b illustrates the device 1 in an unwrapped state.

Each of the members 15, 17 can comprise respective rings 153, 173. In the depicted example, each member comprises 6 rings; however, this is merely illustrative. Each of the rings 153, 173 can comprise a respective ring height 130. The ring height 130 of each ring 153, 173 can vary along the axis Z. In the depicted example, the ring height 130 of each ring 153, 173 varies along the axis Z strictly monotonically; however, this is merely illustrative. Therefore, the quantity of each member 15, 17 can vary along the axis. In other words, the ring height 130 can be an example of the quantity parameter 130, 150 of the varying property 130, 150, 190. In particular, in the depicted example, the quantity of the first member 15 decreases in the direction from top to bottom along the axis Z and the quantity of the second member 17 increases in the direction from top to bottom along the axis Z.

As depicted, each ring 153, 173 can be positioned in the space between two neighboring rings 153, 173 of the other member 15, 17. It will be understood that there can be some spacing in the boundary between the two members 15, 17 that can allow for electrical insulation between the two.

Otherwise, the device 1 illustrated in FIGS. 9a and 9b can comprise any of the features discussed above with respect to the device 1.

Referring now to FIG. 10, another embodiment of the device 1 comprising teethed members 15, 17 is depicted. Not to overload the Figure and/or decrease its intelligibility, only the front teeth 155, 175 (as seen in the depicted perspective view) are hatched. It will be understood that each of the members 15, 17 can also comprise teeth 155, 175 on the back side with respect to the depicted perspective view.

Each of the members 15, 17 can comprise respective teeth 155, 175. Each of the teeth 155, 175 can comprise a respective tooth width 150 which can be constant along the axis Z; however, this is merely illustrative. Moreover, each of the teeth 155, 175 can comprise a respective tooth distance 190, which can indicate an Euclidian distance between the respective tooth 155, 175 and the axis Z. The tooth distance 190 of each tooth 155, 175 can vary along the axis Z. In the depicted example, the tooth distance 190 of each tooth 155, 175 varies along the axis Z linearly; however, this is merely illustrative. Therefore, the distance of each member 15, 17 can vary along the axis Z. In other words, the tooth distance 190 can be an example of the distance parameter 190 of the varying property 130, 150, 190. In particular, in the depicted example, the distance of the first member 15 increases in the direction from top to bottom along the axis Z and the distance of the second member 17 decreases in the direction from top to bottom along the axis Z.

As depicted, the member 15, 17 can comprise interlocking teeth 155, 175. That is, each tooth 155, 175 can be positioned in the space between two neighboring teeth 155, 175 of the other member 15, 17. It will be understood that there can be some spacing in the boundary between the two members 15, 17 that can allow for electrical insulation between the two.

Otherwise, the device 1 illustrated in FIG. 10 can comprise any of the features discussed above with respect to the device 1.

FIG. 11 is a graph illustrating the electric potential at and near the electrical component 2 and at the device 1. In particular, FIG. 11 is a graph comprising a vertical axis which indicates a position along the axis Z and a horizontal axis which indicates an electric potential. In other words, FIG. 11 comprises plots of electric potentials against the position along the axis Z.

The graph depicts with a dashed line the electric potential at the electrical component 2, which is referred to as the first electric potential V1. As it can be noticed, the first electric potential V1 decreases linearly along the axis. For example, the electrical component 2 can be a resistor 2.

Again, an aim of the present invention is to have the electric potential around the electrical component to match (ideally to be identical) to the first electric potential V1.

The graph depicts with a solid line an electric potential around the electrical component 2 when the device 1 of the present invention is used. In particular, the graph depicts with a solid line an average electric potential within the region 3 along the axis Z. This can be referred to as the second electric potential V2. As it can be noticed, the second electric potential V2 matches (i.e., is substantially the same as) the first electric potential V1.

The graph also depicts with a dotted line an effective electric potential V3 of the device 1. It will be understood that within the members 15, 17 of the device 1, the electric potential along the axis Z can be substantially constant. However, due to the canceling or averaging effect that the members 15, 17 can have on each other, the device 1 can comprise an effective electric potential V3 as illustrated in FIG. 11. In other words, by configuring the members 15, 17 as discussed above, the device 1 can affect the electrical component 2 in a similar manner as if its electric potential along the axis Z is the same as the effective electric potential V3.

As it can be noticed, at a top position along the axis Z—which can correspond to the position wherein the first component end 22 can be located—the effective electric potential V3 of the device 1 is at maximum. It can be noticed that the maximums of V1 and V3 are the same, which can be an indication that in this example, the first component end 22 and one of the members 15, 17 (e.g., the first member 15) are electrically connected to the same voltage source. Moreover, moving along the axis Z from said top position, the effective electric potential V3 of the device 1 does not change. This is due to the fact that in this region, the device 1 may consist only of the first member 15—see, e.g., FIGS. 3a to 9b.

On the other hand, at a bottom position along the axis Z—which can correspond to the position wherein the second component end 24 can be located—the effective electric potential V3 of the device 1 is at minimum. Near said bottom position, the effective electric potential V3 of the device 1 does not change. This is due to the fact that in this region, the device 1 may consist only of the second member 17—see, e.g., FIGS. 3a to 9b.

In between these two regions, the effective electric potential V3 changes gradually from the maximum vale to the minimum value—matching the first electric potential V1. Ideally, the members 15, 17 can be configured such that the effective electric potential V3 is identical to the first electric potential V1—as this would completely reduce the capacitance between the device 1 and the electrical component 2. However, satisfactory results can also be achieved with the effective electric potential V3 illustrated in FIG. 11.

FIGS. 12a and 12b illustrates a material composition of the device 1.

As depicted in FIG. 12a, the device 1 can comprise a conductive layer 104 which can be between a substrate layer 102 and a cover layer 106. The cover layer 106 and the substrate layer 102 can be electrically non-conductive. For example, the substrate layer 102 and the cover layer 106 can be made of an electrically non-conductive material, such as, a polyimide material. In some embodiments, the cover layer 106 and the substrate layer 102 can be identical. In some embodiments, the conductive layer 104 can be embedded on the substrate layer 102.

As depicted in FIG. 12b, the conductive layer 104 can comprise two conductive layer portions 1045, 1047 that can be electrically insulated from each other. Each of the members 15, 17 can comprise a respective one of the two conductive layer portions 1045, 1047. Moreover, the two conductive layer portions 1045, 1047 can be spaced apart from each other as indicated by the spacing 1049. This can facilitate electrically insulating the two conductive layer portions 1045, 1047 and thereby the two members 15, 17. The spacing 1049 can comprise a width of at least 0.5 mm, such as 1 mm.

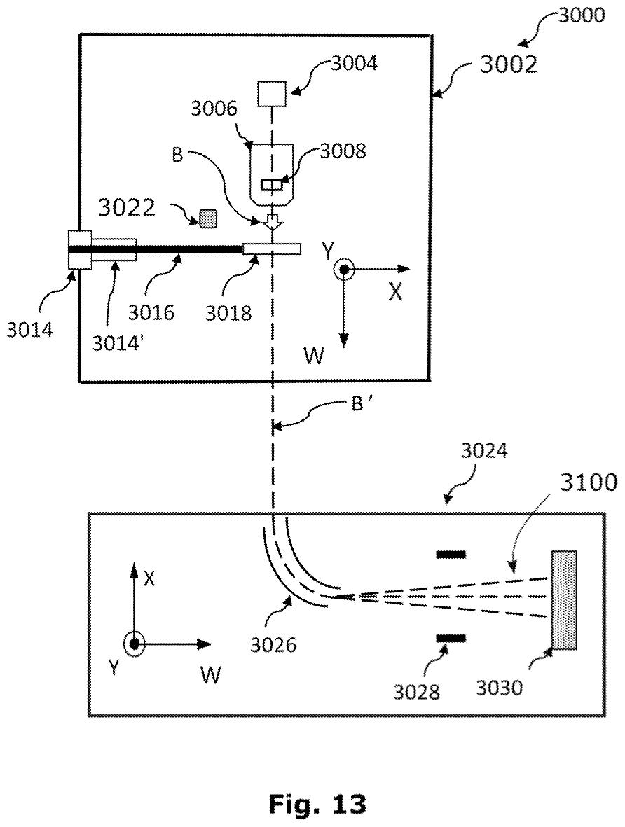

FIG. 13 depicts an embodiment of a microscopy system 3000 which can comprise the device 1 of the present invention. In particular, FIG. 13 depicts a charged particle microscopy system 3000 configured to use a charged particle beam B to observe and/or characterize a sample 3018. The charged particle beam B may comprise electrons or ions. In the particular case depicted in FIG. 13, it comprises electrons. Additionally, the microscopy system 3000 depicted in FIG. 13 may comprise a transmission-type microscopy system 3000, wherein an image of the sample 3018 is taken using the emissions in the transmission region of the microscopy system 3000. Thus, the microscopy system 3000 may represent a Transmission Electron Microscope (TEM) or a Scanning Transmission Electron Microscope (STEM).

As depicted in FIG. 13, within a vacuum enclosure 3002, a changed particle emitter 3004 which in this case is an electron source 3004 can produce the beam B of electrons that can propagate along an electron-optical axis B′ (illustrated by dashed lines). The beam B can traverse an electron-optical illuminator 3006 which can be configured to direct and/or focus the electron beam B onto a chosen part of the sample 3018. Also depicted is a deflector 3008, which (inter alia) can be used to effect scanning motion of the beam B.

The sample 3018 may be held on a sample holder 3016 that can be positioned in multiple degrees of freedom by a positioning device 3014. The latter can move a cradle 3014′ into which the holder 3016 can be affixed, preferably in a removable manner. As such, different parts of the sample 3018 can be illuminated, imaged and/or inspected by the electron beam B traveling along axis B′ (in the W direction). Said movement(s) may also allow scanning motion to be performed, as an alternative to beam scanning.

The electron beam B will interact with the sample 3018 in such a manner as to cause various types of “stimulated” radiation to emanate from the sample 3018. The “stimulated” radiation may include, e.g., secondary electrons, backscattered electrons, X-rays and optical radiation (cathodoluminescence). If desired, one or more of these radiation types can be detected with the aid of analysis device 3022, which might be a combined scintillator/photomultiplier or EDX (Energy-Dispersive X-Ray Spectroscopy) module, for instance. However, alternatively or additionally, one can study electrons that traverse through the sample 3018, exit or emanate from it and propagate along axis B′.

Such a transmitted electron flux can enter an imaging system 3024, which can also be referred to as an energy filter 3024. In particular, when the microscopy system 3000 is used for electron energy loss spectroscopy, the imaging system 3024 may comprise an offset drift tube 3026. The offset drift tube 3026 may comprise a region where a magnetic field (not shown) may be applied to the electron beam B. The magnetic field may be applied in a direction substantially parallel to the Y-direction in the configuration depicted in FIG. 13 such that the path of the electrons in the beam B is curved in the plane depicted in FIG. 13. The electrons may describe a substantially circular path under the influence of the magnetic force resulting from interaction with the magnetic field B, where the radius of the circular path may be based on the speed of the electron. Electrons with a higher speed travel on a path with a larger radius. Thus, the electron beam is split along the X-direction (the dispersive dimension in the configuration of FIG. 13) at the exit of the offset drift tube 3026 depending on the speed (and so, the energy) of the electrons.

To generate the magnetic field, an electric potential can be applied to the offset drift tube 3026, which can be referred to as a drift tube bias voltage. In other words, the magnetic field generated by the offset drift tube 3026 depends on the drift tube bias voltage and so does the way that the electron beam B is split along the X-direction. As such, based on the drift tube bias voltage a particular spectrum of the electron beam B can be incident at the electron sensor 3030—as discussed below. To acquire different parts of the spectrum the bias voltage of the offset drift tube 3026 needs to switch between setpoint voltages with a high frequency. The use of a linear amplifier as a driver of the offset drift tube 3026 can be advantageous, but it may require a high voltage/high ohmic resistor divider. The stray capacitance of the measurement resistor has shown to be a limiting factor. This device 1 of the present invention can take away such limitations.

The electrons emitted from the offset drift tube 3026 may then enter an imaging sub-system 3028 that may also comprise a variety of electrostatic or magnetic lenses, deflectors, correctors (such as stigmators), etc. The imaging sub-system 3028 may be configured, for example, to cause a spread of the electron beam B in the Y-direction (the non-dispersive dimension in the configuration of FIG. 13) as described above. The 2-dimensional electron spectrum 3100, representative of the electron energy spectrum, may then be acquired by an electron sensor 3030. The electron sensor 3030 may comprise a direct or indirect detection sensor. The electron sensor 3030 may comprise a significantly 2-dimensional receiving section comprising a plurality of pixels over which the 2-dimensional electron spectrum, that is acquired as the 2-dimensional electron spectrum 3100, may be incident. The sensor 3030 may be configured to detect the pixel location on which a number of electrons in excess of a threshold number are incident. This may correspond to a detection of electrons at that pixel location.

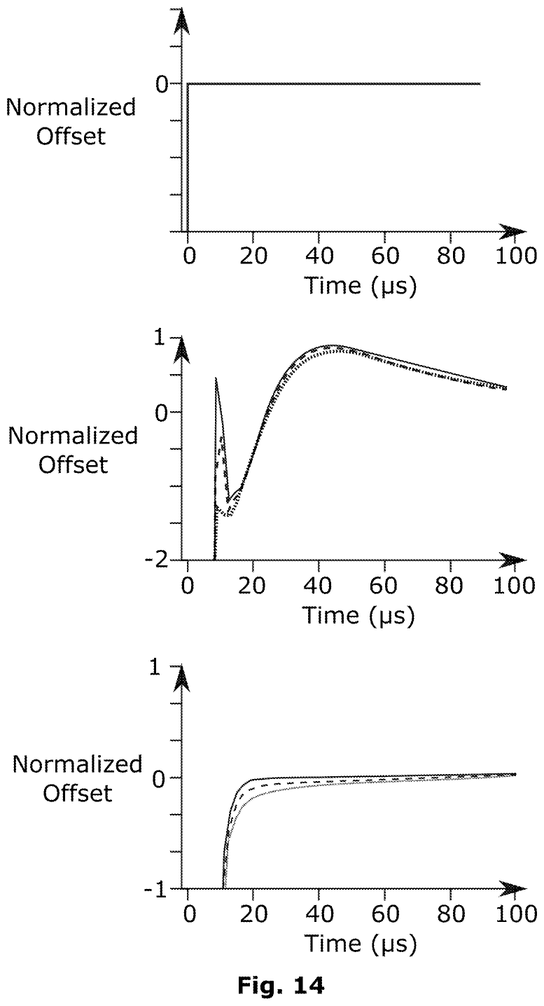

FIG. 14 illustrates respective step responses of an electrical circuit when its input voltage changes for different scenarios. In particular, FIG. 14 illustrates the time behavior of the voltage of an electrical circuit comprising the electrical component 2 when its input voltage changes.

In each of the graphs of FIG. 14, the horizontal axis indicates the time. For example, the horizontal axis in each graph can indicate the time from 0 to 100 micro-seconds after changing the input voltage, wherein each tick can indicate time increments of 20 micro-seconds. The vertical axis can indicate the normalized offset voltage, e.g., the difference between the instantaneous and applied voltage. Therefore, each graph of FIG. 14 can indicate how fast and how well the voltage of an electrical circuit can be changed.

The top graph of FIG. 14 illustrates an ideal scenario. As indicated therein, in an ideal scenario the voltage of an electrical circuit can be changed instantaneously.

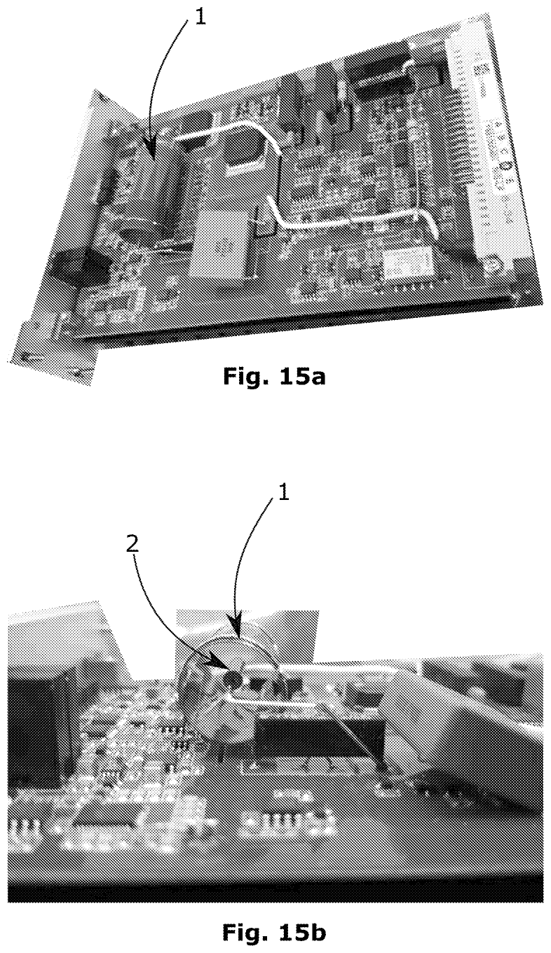

The middle and bottom graphs of FIG. 14 illustrate the step response of an offset drift tube (see FIG. 13) when its bias voltage is changed and when an amplifier circuit comprising a voltage divider circuit is used. The continuous, dashed and dotted line, each depict the step response for different step sizes, i.e., for different changes of the input voltage from one level to the other. In the scenario corresponding to the middle plot the device 1 of the present invention is not used. In the scenario corresponding to the bottom plot the device 1 of the present invention is used around a resistor of the voltage divider circuit (see FIG. 15).

As it is shown by the middle plot, the behavior of the circuit is unstable, particularly for the initial 50 μs. During that time, high voltage peaks can be observed—which can be damaging for the circuit. Only after approximately 100 μs does the voltage of the circuit settle. The complex frequency response observed in the middle plot is mainly due to the parasitic capacitances created by the high ohmic resistor divider used with the amplifier circuit for setting the bias voltage of an offset drift tube.

As shown in the bottom plot, the use of the device 1 causes the voltage of the circuit to settle at around 20 μs. Moreover, the response is very similar to a square response (as indicated in the top plot)—without any voltage peaks.

FIG. 14 therefore shows how the use of the device 1 can reduce the effects caused by the parasitic capacitances in an electrical circuit.

FIGS. 15a and 15b illustrate an electrical circuit wherein the device 1 is used. In particular, FIG. 15a depicts a perspective view of the entire circuit and FIG. 15b depicts a close-up view of the device 1 surrounding a electrical component 2 of the electrical circuit. In the depicted example, the electrical circuit can be a driver for an external electrical device, such as, for an offset drift tube. That is the depicted electrical circuit can be configured to set and to change a bias voltage of an external electrical device, such as, of an offset drift tube. Moreover, the electrical component 2 surrounded by the device 1 can be a resistor 2, such as a high ohmic resistor 2.

Whenever a relative term, such as “about”, “substantially” or “approximately” is used in this specification, such a term should also be construed to also include the exact term. That is, e.g., “substantially straight” should be construed to also include “(exactly) straight”.

Whenever steps were recited in the above or also in the appended claims, it should be noted that the order in which the steps are recited in this text may be accidental. That is, unless otherwise specified or unless clear to the skilled person, the order in which steps are recited may be accidental. That is, when the present document states, e.g., that a method comprises steps (A) and (B), this does not necessarily mean that step (A) precedes step (B), but it is also possible that step (A) is performed (at least partly) simultaneously with step (B) or that step (B) precedes step (A). Furthermore, when a step (X) is said to precede another step (Z), this does not imply that there is no step between steps (X) and (Z). That is, step (X) preceding step (Z) encompasses the situation that step (X) is performed directly before step (Z), but also the situation that (X) is performed before one or more steps (Y1), . . . , followed by step (Z). Corresponding considerations apply when terms like “after” or “before” are used.

While in the above, a preferred embodiment has been described with reference to the accompanying drawings, the skilled person will understand that this embodiment was provided for illustrative purpose only and should by no means be construed to limit the scope of the present invention, which is defined by the claims.

1. A device for use with an electrical component,
wherein the device is configured to surround at least a component portion of the electrical component at least partially around an axis thereby defining a region therebetween,
wherein the device comprises two members, and
wherein at least one of the members comprises at least one varying property that varies along the axis such that an effect caused by a capacitance between the electrical component and an environment wherein the electrical component is positioned is reduced.

2. The device of claim 1, wherein the electrical component is a resistor.

3. The device of claim 1, wherein the effect comprises one or both of a charging time and a discharging time of a capacitor created by the electrical component and the device.

4. The device of claim 1, wherein the effect comprises a time delay in changing, from a first set voltage to a second set voltage, one or both of:
an electric potential of the electrical component, and
an electric potential of an external electrical device electrically connected with the electrical component.

5. The device of claim 1, wherein both members respectively comprise at least one varying property that varies along the axis, and
wherein the members are configured such that the at least one varying property of one of the members and the at least one varying property of the other one of the members increase monotonically according to opposite directions along the axis.

6. The device of claim 1, wherein one of the at least one varying property is a quantity parameter, and
wherein the quantity parameter is indicative of a quantity of the respective member comprised by the device at a plurality of positions along the axis.

7. The device of claim 1, wherein one of the at least one varying property is a distance parameter, and
wherein the distance parameter is indicative of a radial distance between the respective member and the axis measured radially with respect to the axis.

8. The device of claim 1, wherein:
the device comprises a first device end and a second device end opposite to each other and at different positions along the axis;
a first one of the members extends along the axis from the first device end, past a center of the device and towards the second device end; and
a second one of the members extends along the axis from the second device end, past the center of the device and towards the first device end.

9. The device of claim 1, wherein the members are configured such that any radial line perpendicular with the axis passes through at most one of the members.

10. The device of claim 1, wherein one or both of:
(i) at least one of the members comprises at least one tooth extending parallel to the axis; and
(ii) wherein both of the members respectively comprise a plurality of teeth extending parallel to the axis.

11. The device of claim 10, wherein each tooth extends along the axis from a first half of the device to a second half of the device, wherein the first and the second halves of the device are separated by a plane perpendicular to the axis.

12. The device of claim 10, wherein each tooth comprises a respective tooth width spanning azimuthally with respect to the axis,
wherein each tooth is configured such that its respective tooth width tapers along the axis, and
wherein one of the at least one varying property depends on the tooth width of at least one tooth.

13. The device of claim 10, wherein each tooth comprises a respective tooth distance from the axis measured radially with respect to the axis,
wherein each tooth is configured such that its respective tooth distance varies monotonically along the axis, and
wherein one of the at least one varying property depends on the tooth distance of at least one tooth.

14. The device of claim 1, wherein:
at least one of the members comprises a plurality of rings,
each ring comprises a respective ring height measured along the axis,
the ring height of rings comprised by the same member varies monotonically along the axis, and
wherein one of the at least one varying property depends on the ring height of at least one ring.

15. A system comprising:
a device; and
an electrical component,
wherein the device is configured to surround at least a component portion of the electrical component at least partially around an axis thereby defining a region therebetween,
wherein the device comprises two members, and
wherein at least one of the members comprises at least one varying property that varies along the axis such that an effect caused by a capacitance between the electrical component and an environment wherein the electrical component is positioned is reduced.

16. The system of claim 15, wherein the system further comprises an offset drift tube for use in a charged particle microscope, and wherein:
the electrical component is electrically connected with the offset drift tube,
the offset drift tube comprises a region traversable by a charged particle beam, and
the offset drift tube is configured to generate a magnetic field in said region.

17. A method of operating an electrical component comprising:
providing a device surrounding at least a component portion of the electrical component at least partially around an axis thereby defining a region therebetween,
wherein the device comprises two members,
wherein at least one of the members comprises at least one varying property that varies along the axis such that an effect caused by a capacitance between the electrical component and an environment wherein the electrical component is positioned is reduced,
wherein the electrical component comprises two component ends opposite to each other and at different positions along the axis, and
wherein the method comprises maintaining each member and a respective one of the component ends at equal electric potentials.

18-20. (canceled)

21. The method of claim 17, further comprising electrically connecting the device to an electrical energy source, wherein electrically connecting the device to an electrical energy source comprises electrically connecting each of the members to a respective one of opposite terminals of the electrical energy source.

22. The method of claim 17, wherein electrically connecting the device to an electrical energy source comprises electrically connecting the device and the electrical component to the same electrical energy source.

23. The method of claim 17, wherein the electrical energy source is an alternating current source.
